(19) United States
(12) Patent Application Publication
(10) Pub. No.: US 2024/0242764 A1
(43) Pub. Date: Jul. 18, 2024

(54) PROGRAMMING TECHNIQUES IN A MEMORY DEVICE TO REDUCE A HYBRID SLC RATIO

(71) Applicant: SanDisk Technologies LLC, Addison, TX (US)

(72) Inventors: Huiwen Xu, Cupertino, CA (US); Deepanshu Dutta, Fremont, CA (US); Jia Li, San Francisco, CA (US); Bo Lei, San Jose, CA (US); Ken Oowada, Fujisawa (JP)

(73) Assignee: SanDisk Technologies LLC, Addison, TX (US)

(21) Appl. No.: 18/222,735

(22) Filed: Jul. 17, 2023

Related U.S. Application Data
(60) Provisional application No. 63/438,837, filed on Jan. 13, 2023.

(51) Int. Cl. G11C 16/10; G11C 16/04; G11C 16/08

(52) U.S. Cl. CPC G11C 16/102; G11C 16/0433; G11C 16/08

(57) ABSTRACT

The memory device includes a plurality of hybrid memory blocks that can operate in either a single bit per memory cell mode or a multiple bits per memory cell mode. The memory blocks each include a plurality of memory cells, which are arranged in a plurality of word lines. Control circuitry is configured to program a selected word line to an SLC format. The control circuitry is further configured to determine which zone within the selected hybrid memory block the selected word line is located in and set an SLC programming voltage to a level based on the determination of the zone of the selected word line. The control circuitry is further configured to apply a programming pulse at the SLC programming voltage to the selected word line to program the memory cells of the selected word line.

### CROSS-REFERENCE TO RELATED APPLICATIONS

This application claims the benefit of U.S. Provisional Application No. 63/438,837, filed on Jan. 13, 2023. The entire disclosure of the application referenced above is incorporated herein by reference.

### BACKGROUND

### 1. Field

The present disclosure is related to techniques for programming NAND memory devices and more particularly to techniques for programming NAND memory devices to reduce a hybrid SLC (hSLC) ratio.

### 2. Related Art

Semiconductor memory is widely used in various electronic devices, such as cellular telephones, digital cameras, personal digital assistants, medical electronics, mobile computing devices, servers, solid state drives, non-mobile computing devices and other devices. Semiconductor memory may comprise non-volatile memory or volatile memory. A non-volatile memory allows information to be stored and retained even when the non-volatile memory is not connected to a source of power, e.g., a battery.

NAND memory devices include a chip with a plurality of memory blocks, each of which includes an array of memory cells arranged in a plurality of word lines. A pair of example memory blocks 100, 110 are illustrated in a FIG. 1. In this example, the memory blocks 100, 110 have a two-dimensional configuration. A memory array in the chip can include many such blocks 100, 110. Each example block 100, 110 includes a number of NAND strings and respective bit lines, e.g., BL0, BL1, . . . which are shared among the blocks. Each NAND string is connected at one end to a drain-side select gate (SGD), and the control gates of the drain select gates are connected via a common SGD line. The NAND strings are connected at their other end to a source-side select gate (SGS) which, in turn, is connected to a common source line 120. One hundred and twelve word lines, for example, WL0-WL111, extend between the SGSs and the SGDs. In some embodiments, the memory block may include more or fewer than one hundred and twelve word lines. For example, in some embodiments, a memory block includes one hundred and sixty-four word lines. In some cases, dummy word lines, which contain no user data, can also be used in the memory array adjacent to the select gate transistors. Such dummy word lines can shield the edge data word line from certain edge effects.

One type of non-volatile memory which may be provided in the memory array is a floating gate memory, such as of the type shown in FIGS. 2A and 2B. However, other types of non-volatile memory can also be used. As discussed in further detail below, in another example shown in FIGS. 3A and 3B, a charge-trapping memory cell uses a non-conductive dielectric material in place of a conductive floating gate to store charge in a non-volatile manner. A triple layer dielectric formed of silicon oxide, silicon nitride and silicon oxide (“ONO”) is sandwiched between a conductive control gate and a surface of a semi-conductive substrate above the memory cell channel. The cell is programmed by injecting electrons from the cell channel into the nitride, where they are trapped and stored in a limited region. This stored charge then changes the threshold voltage of a portion of the channel of the cell in a manner that is detectable. The cell is erased by injecting hot holes into the nitride. A similar cell can be provided in a split-gate configuration where a doped polysilicon gate extends over a portion of the memory cell channel to form a separate select transistor.

In another approach, NROM cells are used. Two bits, for example, are stored in each NROM cell, where an ONO dielectric layer extends across the channel between source and drain diffusions. The charge for one data bit is localized in the dielectric layer adjacent to the drain, and the charge for the other data bit localized in the dielectric layer adjacent to the source. Multi-state data storage is obtained by separately reading binary states of the spatially separated charge storage regions within the dielectric. Other types of non-volatile memory are also known.

FIG. 2A illustrates a cross-sectional view of example floating gate memory cells 200, 210, 220 in NAND strings. In this Figure, a bit line or NAND string direction goes into the page, and a word line direction goes from left to right. As an example, word line 224 extends across NAND strings which include respective channel regions 206, 216 and 226. The memory cell 200 includes a control gate 202, a floating gate 204, a tunnel oxide layer 205 and the channel region 206. The memory cell 210 includes a control gate 212, a floating gate 214, a tunnel oxide layer 215 and the channel region 216. The memory cell 220 includes a control gate 222, a floating gate 221, a tunnel oxide layer 225 and the channel region 226. Each memory cell 200, 210, 220 is in a different respective NAND string. An inter-poly dielectric (IPD) layer 228 is also illustrated. The control gates 202, 212, 222 are portions of the word line. A cross-sectional view along contact line connector 229 is provided in FIG. 2B.

The control gate 202, 212, 222 wraps around the floating gate 204, 214, 221, increasing the surface contact area between the control gate 202, 212, 222 and floating gate 204, 214, 221. This results in higher IPD capacitance, leading to a higher coupling ratio which makes programming and erase easier. However, as NAND memory devices are scaled down, the spacing between neighboring cells 200, 210, 220 becomes smaller so there is almost no space for the control gate 202, 212, 222 and the IPD layer 228 between two adjacent floating gates 202, 212, 222.

As an alternative, as shown in FIGS. 3A and 3B, the flat or planar memory cell 300, 310, 320 has been developed in which the control gate 302, 312, 322 is flat or planar; that is, it does not wrap around the floating gate and its only contact with the charge storage layer 328 is from above it. In this case, there is no advantage in having a tall floating gate. Instead, the floating gate is made much thinner. Further, the floating gate can be used to store charge, or a thin charge trap layer can be used to trap charge. This approach can avoid the issue of ballistic electron transport, where an electron can travel through the floating gate after tunneling through the tunnel oxide during programming.

FIG. 3A depicts a cross-sectional view of example charge-trapping memory cells 300, 310, 320 in NAND strings. The view is in a word line direction of memory cells 300, 310, 320 comprising a flat control gate and charge-trapping regions as a two-dimensional example of memory cells 300, 310, 320 in the memory cell array 126. Charge-trapping memory can be used in NOR and NAND flash memory device. This technology uses an insulator such as an SiN film to store electrons, in contrast to a floating-gate MOSFET technology which uses a conductor such as doped polycrystalline silicon to store electrons. As an example, a word line 324 extends across NAND strings which include respective channel regions 306, 316, 326. Portions of the word line provide control gates 302, 312, 322. Below the word line is an IPD layer 328, charge-trapping layers 304, 314, 321, polysilicon layers 305, 315, 325, and tunneling layers 309, 307, 308. Each charge-trapping layer 304, 314, 321 extends continuously in a respective NAND string. The flat configuration of the control gate can be made thinner than a floating gate. Additionally, the memory cells can be placed closer together.

FIG. 3B illustrates a cross-sectional view of the structure of FIG. 3A along contact line connector 329. The NAND string 330 includes an SGS transistor 331, example memory cells 300, 333, . . . 335, and an SGD transistor 336. Passageways in the IPD layer 328 in the SGS and SGD transistors 331, 336 allow the control gate layers 302 and floating gate layers to communicate. The control gate 302 and floating gate layers may be polysilicon and the tunnel oxide layer may be silicon oxide, for instance. The IPD layer 328 can be a stack of nitrides (N) and oxides (O) such as in a N—O—N—O—N configuration.

The NAND string may be formed on a substrate which comprises a p-type substrate region 355, an n-type well 356 and a p-type well 357. N-type source/drain diffusion regions sd1, sd2, sd3, sd4, sd5, sd6 and sd7 are formed in the p-type well. A channel voltage, Vch, may be applied directly to the channel region of the substrate.

FIG. 4 illustrates an example block diagram of a sense block SB1 in a memory chip. In one approach, a sense block comprises multiple sense circuits. Each sense circuit is associated with data latches. For example, the example sense circuits 450a, 451a, 452a, and 453a are associated with the data latches 450b, 451b, 452b, and 453b, respectively. In one approach, different subsets of bit lines can be sensed using different respective sense blocks. This allows the processing load which is associated with the sense circuits to be divided up and handled by a respective processor in each sense block. For example, a sense circuit controller 460 in SB1 can communicate with the set of sense circuits and latches. The sense circuit controller 460 may include a pre-charge circuit 461 which provides a voltage to each sense circuit for setting a pre-charge voltage. In one possible approach, the voltage is provided to each sense circuit independently, e.g., via the data bus and a local bus. In another possible approach, a common voltage is provided to each sense circuit concurrently. The sense circuit controller 460 may also include a pre-charge circuit 461, a memory 462 and a processor 463. The memory 462 may store code which is executable by the processor to perform the functions described herein. These functions can include reading the latches 450b, 451b, 452b, 453b which are associated with the sense circuits 450a, 451a, 452a, 453a, setting bit values in the latches and providing voltages for setting pre-charge levels in sense nodes of the sense circuits 450a, 451a, 452a, 453a. Further example details of the sense circuit controller 460 and the sense circuits 450a, 451a, 452a, 453a are provided below.

In some embodiments, a memory cell may include a flag register that includes a set of latches storing flag bits. In some embodiments, a quantity of flag registers may correspond to a quantity of data states. In some embodiments, one or more flag registers may be used to control a type of verification technique used when verifying memory cells. In some embodiments, a flag bit's output may modify associated logic of the device, e.g., address decoding circuitry, such that a specified block of cells is selected. A bulk operation (e.g., an erase operation, etc.) may be carried out using the flags set in the flag register, or a combination of the flag register with the address register, as in implied addressing, or alternatively by straight addressing with the address register alone.

FIG. 5A is a perspective view of a set of blocks 500 in an example three-dimensional configuration. On the substrate are example blocks BLK0, BLK1, BLK2, BLK3 of memory cells (storage elements) and a peripheral area 504 with circuitry for use by the blocks BLK0, BLK1, BLK2, BLK3. For example, the circuitry can include voltage drivers 505 which can be connected to control gate layers of the blocks BLK0, BLK1, BLK2, BLK3. In one approach, control gate layers at a common height in the blocks BLK0, BLK1, BLK2, BLK3 are commonly driven. The substrate 501 can also carry circuitry under the blocks BLK0, BLK1, BLK2, BLK3, along with one or more lower metal layers which are patterned in conductive paths to carry signals of the circuitry. The blocks BLK0, BLK1, BLK2, BLK3 are formed in an intermediate region 502 of the memory device. In an upper region 503 of the memory device, one or more upper metal layers are patterned in conductive paths to carry signals of the circuitry. Each block BLK0, BLK1, BLK2, BLK3 comprises a stacked area of memory cells, where alternating levels of the stack represent word lines. In one possible approach, each block BLK0, BLK1, BLK2, BLK3 has opposing tiered sides from which vertical contacts extend upward to an upper metal layer to form connections to conductive paths. While four blocks BLK0, BLK1, BLK2, BLK3 are illustrated as an example, two or more blocks can be used, extending in the x- and/or y-directions.

In one possible approach, the length of the plane, in the x-direction, represents a direction in which signal paths to word lines extend in the one or more upper metal layers (a word line or SGD line direction), and the width of the plane, in the y-direction, represents a direction in which signal paths to bit lines extend in the one or more upper metal layers (a bit line direction). The z-direction represents a height of the memory device.

FIG. 5B illustrates an example cross-sectional view of a portion of one of the blocks BLK0, BLK1, BLK2, BLK3 of FIG. 5A. The block comprises a stack 510 of alternating conductive and dielectric layers. In this example, the conductive layers comprise two SGD layers, two SGS layers and four dummy word line layers DWLD0, DWLD1, DWLS0 and DWLS1, in addition to data word line layers (word lines) WL0-WL111. The dielectric layers are labelled as DL0-DL116. Further, regions of the stack 510 which comprise NAND strings NS1 and NS2 are illustrated. Each NAND string encompasses a memory hole 518, 519 which is filled with materials which form memory cells adjacent to the word lines. A region 522 of the stack 510 is shown in greater detail in FIG. 5D and is discussed in further detail below.

The stack 510 includes a substrate 511, an insulating film 512 on the substrate 511, and a portion of a source line SL. NS1 has a source-end 513 at a bottom 514 of the stack and a drain-end 515 at a top 516 of the stack 510. Contact line connectors (e.g., slits, such as metal-filled slits) 517, 520 may be provided periodically across the stack 510 as interconnects which extend through the stack 510, such as to connect the source line to a particular contact line above the stack 510. The contact line connectors 517, 520 may be used during the formation of the word lines and subsequently filled with metal. A portion of a bit line BL0 is also illustrated. A conductive via 521 connects the drain-end 515 to BL0.

FIG. 5C illustrates a plot of memory hole diameter in the stack of FIG. 5B. The vertical axis is aligned with the stack of FIG. 5B and illustrates a width (wMH), e.g., diameter, of the memory holes 518 and 519. The word line layers WL0-WL111 of FIG. 5A are repeated as an example and are at respective heights z0-z111 in the stack. In such a memory device, the memory holes which are etched through the stack have a very high aspect ratio. For example, a depth-to-diameter ratio of about 25-30 is common. The memory holes may have a circular cross-section. Due to the etching process, the memory hole width can vary along the length of the hole. Typically, the diameter becomes progressively smaller from the top to the bottom of the memory hole. That is, the memory holes are tapered, narrowing at the bottom of the stack. In some cases, a slight narrowing occurs at the top of the hole near the select gate so that the diameter becomes slightly wider before becoming progressively smaller from the top to the bottom of the memory hole.

FIG. 5D illustrates a close-up view of the region 522 of the stack 510 of FIG. 5B. Memory cells are formed at the different levels of the stack at the intersection of a word line layer and a memory hole. In this example, SGD transistors 580, 581 are provided above dummy memory cells 582, 583 and a data memory cell MC. A number of layers can be deposited along the sidewall (SW) of the memory hole 530 and/or within each word line layer, e.g., using atomic layer deposition. For example, each column (e.g., the pillar which is formed by the materials within a memory hole 530) can include a charge-trapping layer or film 563 such as SiN or other nitride, a tunneling layer 564, a polysilicon body or channel 565, and a dielectric core 566. A word line layer can include a blocking oxide/block high-k material 560, a metal barrier 561, and a conductive metal 562 such as Tungsten as a control gate. For example, control gates 590, 591, 592, 593, and 594 are provided. In this example, all of the layers except the metal are provided in the memory hole 530. In other approaches, some of the layers can be in the control gate layer. Additional pillars are similarly formed in the different memory holes. A pillar can form a columnar active area (AA) of a NAND string.

When a memory cell is programmed, electrons are stored in a portion of the charge-trapping layer which is associated with the memory cell. These electrons are drawn into the charge-trapping layer from the channel, and through the tunneling layer. The Vth of a memory cell is increased in proportion to the amount of stored charge. During an erase operation, the electrons return to the channel.

Each of the memory holes 530 can be filled with a plurality of annular layers comprising a blocking oxide layer, a charge trapping layer 563, a tunneling layer 564 and a channel layer. A core region of each of the memory holes 530 is filled with a body material, and the plurality of annular layers are between the core region and the word line in each of the memory holes 530.

The NAND string can be considered to have a floating body channel because the length of the channel is not formed on a substrate. Further, the NAND string is provided by a plurality of word line layers above one another in a stack, and separated from one another by dielectric layers.

FIG. 7A illustrates a top view of an example word line layer WL0 of the stack 510 of FIG. 5B. As mentioned, a three-dimensional memory device can comprise a stack of alternating conductive and dielectric layers. The conductive layers provide the control gates of the SG transistors and memory cells. The layers used for the SG transistors are SG layers and the layers used for the memory cells are word line layers. Further, memory holes are formed in the stack and filled with a charge-trapping material and a channel material. As a result, a vertical NAND string is formed. Source lines are connected to the NAND strings below the stack and bit lines are connected to the NAND strings above the stack.

A block BLK in a three-dimensional memory device can be divided into sub-blocks, where each sub-block comprises a NAND string group which has a common SGD control line. For example, see the SGD lines/control gates SGD0, SGD1, SGD2 and SGD3 in the sub-blocks SBa, SBb, SBc and SBd, respectively. Further, a word line layer in a block can be divided into regions. Each region is in a respective sub-block and can extend between contact line connectors (e.g., slits) which are formed periodically in the stack to process the word line layers during the fabrication process of the memory device. This processing can include replacing a sacrificial material of the word line layers with metal. Generally, the distance between contact line connectors should be relatively small to account for a limit in the distance that an etchant can travel laterally to remove the sacrificial material, and that the metal can travel to fill a void which is created by the removal of the sacrificial material. For example, the distance between contact line connectors may allow for a few rows of memory holes between adjacent contact line connectors. The layout of the memory holes and contact line connectors should also account for a limit in the number of bit lines which can extend across the region while each bit line is connected to a different memory cell. After processing the word line layers, the contact line connectors can optionally be filed with metal to provide an interconnect through the stack.

In this example, there are four rows of memory holes between adjacent contact line connectors. A row here is a group of memory holes which are aligned in the x-direction. Moreover, the rows of memory holes are in a staggered pattern to increase the density of the memory holes. The word line layer or word line is divided into regions WL0a, WL0b, WL0c and WL0d which are each connected by a contact line 613. The last region of a word line layer in a block can be connected to a first region of a word line layer in a next block, in one approach. The contact line 613, in turn, is connected to a voltage driver for the word line layer. The region WL0a has example memory holes 610, 611 along a contact line 612. The region WL0b has example memory holes 614, 615. The region WL0c has example memory holes 616, 617. The region WL0d has example memory holes 618, 619. The memory holes are also shown in FIG. 6B. Each memory hole can be part of a respective NAND string. For example, the memory holes 610, 614, 616 and 618 can be part of NAND strings NS0_SBa, NS1_SBb, NS2_SBc, NS3_SBd, and NS4_SBe, respectively.

Each circle represents the cross-section of a memory hole at a word line layer or SG layer. Example circles shown with dashed lines represent memory cells which are provided by the materials in the memory hole and by the adjacent word line layer. For example, memory cells 620, 621 are in WL0a, memory cells 624, 625 are in WL0b, memory cells 626, 627 are in WL0c, and memory cells 628, 629 are in WL0d. These memory cells are at a common height in the stack.

Contact line connectors (e.g., slits, such as metal-filled slits) 601, 602, 603, 604 may be located between and adjacent to the edges of the regions WL0a-WL0d. The contact line connectors 601, 602, 603, 604 provide a conductive path from the bottom of the stack to the top of the stack. For example, a source line at the bottom of the stack may be connected to a conductive line above the stack, where the conductive line is connected to a voltage driver in a peripheral region of the memory device.

FIG. 6B illustrates a top view of an example top dielectric layer DL116 of the stack of FIG. 5B. The dielectric layer is divided into regions DL116a, DL116b, DL116c and DL116d. Each region can be connected to a respective voltage driver. This allows a set of memory cells in one region of a word line layer being programmed concurrently, with each memory cell being in a respective NAND string which is connected to a respective bit line. A voltage can be set on each bit line to allow or inhibit programming during each program voltage.

The region DL116a has the example memory holes 610, 611 along a contact line 612, which is coincident with a bit line BL0. A number of bit lines extend above the memory holes and are connected to the memory holes as indicated by the “X” symbols. BL0 is connected to a set of memory holes which includes the memory holes 611, 615, 617, 619. Another example bit line BL1 is connected to a set of memory holes which includes the memory holes 610, 614, 616, 618. The contact line connectors (e.g., slits, such as metal-filled slits) 601, 602, 603, 604 from FIG. 6A are also illustrated, as they extend vertically through the stack. The bit lines can be numbered in a sequence BL0-BL23 across the DL116 layer in the x-direction.

Different subsets of bit lines are connected to memory cells in different rows. For example, BL0, BL4, BL8, BL12, BL16, BL20 are connected to memory cells in a first row of cells at the right-hand edge of each region. BL2, BL6, BL10, BL14, BL18, BL22 are connected to memory cells in an adjacent row of cells, adjacent to the first row at the right-hand edge. BL3, BL7, BL11, BL15, BL19, BL23 are connected to memory cells in a first row of cells at the left-hand edge of each region. BL1, BL5, BL9, BL13, BL17, BL21 are connected to memory cells in an adjacent row of memory cells, adjacent to the first row at the left-hand edge.

The memory cells of the memory blocks can be programmed to retain one or more bits of data in multiple data states, each of which is associated with a respective threshold voltage Vt range. For example, FIG. 7 depicts a threshold voltage Vt distribution of a group of memory cells programmed according to a one bit per memory cell (SLC) storage scheme. In the SLC storage scheme, there are two total data states, including the erased state (Er) and a single programmed data state (S1). FIG. 8 illustrates the threshold voltage Vt distribution of a three bits per cell (TLC) storage scheme that includes eight total data states, namely the erased state (Er) and seven programmed data states (S1, S2, S3, S4, S5, S6, and S7). Each programmed data state (S1-S7) is associated with a respective verify voltage (Vv1-Vv7), which is employed during a verify portion of a programming operation. FIG. 9 depicts a threshold voltage Vt distribution of a four bits per cell (QLC) storage scheme that includes sixteen total data states, namely the erased state (Er) and fifteen programmed data states (S1-S15). Other storage schemes are also available, such as two bits per cell (MLC) with four data states or five bits per cell (PLC) with thirty-two data states. Generally, programming a fixed amount of data into memory cells at a higher number of bits per memory cell (such as TLC or QLC) requires more time than programming the same amount of data into more memory cells at a reduced number of bits per cell. In other words, there is a tradeoff between programming high speed (performance) and programming at high density. Also, programming to TLC or QLC stresses the memory cells more than programming to SLC, and therefore, the endurance (as measured in terabytes written [TBW]) of a memory device programming to SLC is generally greater than the endurance of a memory device programming to TLC or QLC.

### SUMMARY

An aspect of the present disclosure is related to a method of programming a memory device. The method includes the step of preparing a memory device that includes a plurality of memory blocks. Each memory block includes a plurality of memory cells that are arranged in a plurality of word lines. The plurality of memory blocks includes a plurality of hybrid memory blocks that are able to operate in a single bit per memory cell (SLC) mode and are able to operate in a multiple bits per memory cell mode. The method continues with the step of programming a selected word line of the plurality of word lines within a selected hybrid memory block to an SLC format. The programming of the selected word line to the SLC format includes the step of determining which zone within the selected hybrid memory block the selected word line is located in. The method then proceeds with the step of setting an SLC programming voltage to a level based on the determination of the zone of the selected word line. The method then continues with the step of applying a programming pulse at the SLC programming voltage to the selected word line to program the memory cells of the selected word line.

According to another aspect of the present disclosure, the plurality of memory blocks further includes a plurality of dedicated SLC memory blocks that are only configured to operate in the SLC mode.

According to yet another aspect of the present disclosure, the memory cells of the word lines of the dedicated SLC memory blocks are programmed with a programming pulse at a VPGMSLC voltage.

According to still another aspect of the present disclosure, the method further includes the step of setting the SLC programming voltage includes determining a AVPGMSLC voltage based on which zone the selected word line is located in and the step of setting the SLC programming voltage to a level that is equal to VPGMSLC minus AVPGMSLC.

According to a further aspect of the present disclosure, the method further includes, during a background operation, the step of programming any data written to SLC format in either the dedicated SLC memory blocks or the hybrid memory blocks to a multiple bits per memory cell format.

According to yet a further aspect of the present disclosure, the multiple bits per memory cell format includes at least three bits per memory cell.

According to still a further aspect of the present disclosure, the method further includes the step of determining if the programming of the selected word line is to include multiple programming pulses and at least one verify operation or is to include only a single programming pulse and no verify operations based on the determination of which zone the selected word line is located within.

Another aspect of the present disclosure is related to a memory device. The memory device includes a plurality of memory blocks that each include a plurality of memory cells, which are arranged in a plurality of word lines. The plurality of memory blocks include a plurality of hybrid memory blocks that are able to operate in a single bit per memory cell (SLC) mode and a multiple bits per memory cell mode. The memory device further includes control circuitry that is configured to program a selected word line of the plurality of word lines within a selected hybrid memory block to an SLC format. The control circuitry is further configured to determine which zone within the selected hybrid memory block the selected word line is located in and set an SLC programming voltage to a level based on the determination of the zone of the selected word line. The control circuitry is further configured to apply a programming pulse at the SLC programming voltage to the selected word line to program the memory cells of the selected word line.

According to another aspect of the present disclosure, the plurality of memory blocks further includes a plurality of dedicated SLC memory blocks that are only configured to operate in the SLC mode.

According to yet another aspect of the present disclosure, the control circuitry of the memory device is configured to program the memory cells of the word lines of the dedicated SLC memory blocks with a programming pulse at a VPGMSLC voltage.

According to still another aspect of the present disclosure, while setting the SLC programming voltage, the control circuitry is configured to determine a AVPGMSLC voltage based on which zone the selected word line is located in and is configured to set the SLC programming voltage to a level that is equal to VPGMSLC minus AVPGMSLC.

According to a further aspect of the present disclosure, the control circuitry is configured to, during a background operation, program any data written to SLC format in either the dedicated SLC memory blocks or the hybrid memory blocks to a multiple bits per memory cell format.

According to yet a further aspect of the present disclosure, the multiple bits per memory cell format includes at least three bits per memory cell.

According to still a further aspect of the present disclosure, the control circuitry is further configured to determine if the programming of the selected word line is to include multiple programming pulses and at least one verify operation or is to include only a single programming pulse and no verify operations based on the determination of which zone the selected word line is located within.

Yet another aspect of the present disclosure is related to an apparatus. The apparatus includes a plurality of memory blocks that each include a plurality of memory cells, which are arranged in a plurality of word lines. The plurality of memory blocks includes a plurality of hybrid memory blocks that are able to operate in a single bit per memory cell (SLC) mode and a multiple bits per memory cell mode, and the plurality of memory blocks includes a plurality of dedicated SLC memory blocks that are only able to operate in the SLC mode. The apparatus further includes a programming means for programming the memory cells of a selected word line within a selected hybrid memory block to an SLC format. The programming means is configured to determine which zone within the selected hybrid memory block the selected word line is located in, set an SLC programming voltage to a level based on the determination of the zone of the selected word line, and apply a programming pulse at the SLC programming voltage to the selected word line to program the memory cells of the selected word line.

According to another aspect of the present disclosure, the plurality of memory blocks further includes a plurality of dedicated SLC memory blocks that are only configured to operate in the SLC mode.

According to yet another aspect of the present disclosure, the programming means is configured to program the memory cells of the word lines of the dedicated SLC memory blocks with a programming pulse at a VPGMSLC voltage.

According to still another aspect of the present disclosure, while setting the SLC programming voltage, the programming means is configured to determine a AVPGMSLC voltage based on which zone the selected word line is located in and set the SLC programming voltage to a level that is equal to VPGMSLC minus AVPGMSLC.

According to a further aspect of the present disclosure, the programming means is configured to, during a background operation, program any data written to SLC format in either the dedicated SLC memory blocks or the hybrid memory blocks to a multiple bits per memory cell format.

According to yet a further aspect of the present disclosure, the programming means is configured to determine if the programming of the selected word line is to include multiple programming pulses and at least one verify operation or is to include only a single programming pulse and no verify operations based on the determination of which zone the selected word line is located within.

### BRIEF DESCRIPTION OF THE DRAWINGS

A more detailed description is set forth below with reference to example embodiments depicted in the appended figures. Understanding that these figures depict only example embodiments of the disclosure and are, therefore, not to be considered limiting of its scope. The disclosure is described and explained with added specificity and detail through the use of the accompanying drawings in which:

FIG. 1 depicts blocks of memory cells in an example two-dimensional configuration of a memory array:

FIG. 2A and FIG. 2B depict cross-sectional views of example floating gate memory cells in NAND strings:

FIG. 3A and FIG. 3B depict cross-sectional views of example charge-trapping memory cells in NAND strings:

FIG. 4 depicts an example block diagram of a sense block SB1:

FIG. 5A is a perspective view of a set of blocks in an example three-dimensional configuration of a memory array:

FIG. 5B depicts an example cross-sectional view of a portion of one of the blocks of FIG. 5A:

FIG. 5C depicts a plot of memory hole diameter of the stack of FIG. 5B;

FIG. 5D depicts a close-up view of region 522 of the stack of FIG. 5B;

FIG. 6A depicts a top view of an example word line layer WL0 of the stack of FIG. 5B:

FIG. 6B depicts a top view of an example top dielectric layer DL116 of the stack of FIG. 5B;

FIG. 7 depicts a threshold voltage distribution of a page of memory cells programmed to one bit per memory cell (SLC):

FIG. 8 depicts a threshold voltage distribution of a page of memory cells programmed to three bits per memory cell (TLC):

FIG. 9 depicts a threshold voltage distribution of a page of memory cells programmed to four bits per memory cell (QLC):

FIG. 10A is a block diagram of an example memory device:

FIG. 10B is a block diagram of an example control circuit:

FIG. 10C is another block diagram of an example control circuit;

FIG. 11 depicts a voltage waveform of the voltage applied to a control gate of a selected word line during an example programming operation:

FIG. 12 is a schematic view of a memory device according to an exemplary embodiment and illustrating a plurality of dedicated SLC memory blocks and a plurality of hybrid memory blocks;

FIG. 13 is a plot of QLC program-erase cycles versus hybrid SLC (hSLC) ratio for an example memory device:

FIG. 14 is a plot of percentage of programming to in the hSLC mode versus hSLC ratio for different total data written amounts;

FIG. 15A is a threshold voltage distribution plot of a plurality of memory cells programmed to QLC in one of the hybrid memory blocks:

FIG. 15B is a threshold voltage distribution plot of a plurality of memory cells programmed to SLC in one of the hybrid memory blocks:

FIG. 16A is a threshold voltage distribution plot of a plurality of memory cells programmed to SLC:

FIG. 16B is a threshold voltage distribution plot of a plurality of memory cells programmed to SLC using shallow erase and shallow program techniques:

FIG. 17A is a table of different word line zones and corresponding AVPGMSLC voltages in an example hybrid memory block:

FIG. 17B is a table of different word line zones and corresponding AVPGMSLC voltages and programming schemes in an example hybrid memory block:

FIG. 18 is a plot of hSLC ratio versus AVPGMSLC for a range of different word lines in an example hybrid memory block; and

FIG. 19 is a flowchart illustrating the steps of programming the memory cells of an example hybrid memory block according to an exemplary embodiment of the present disclosure.

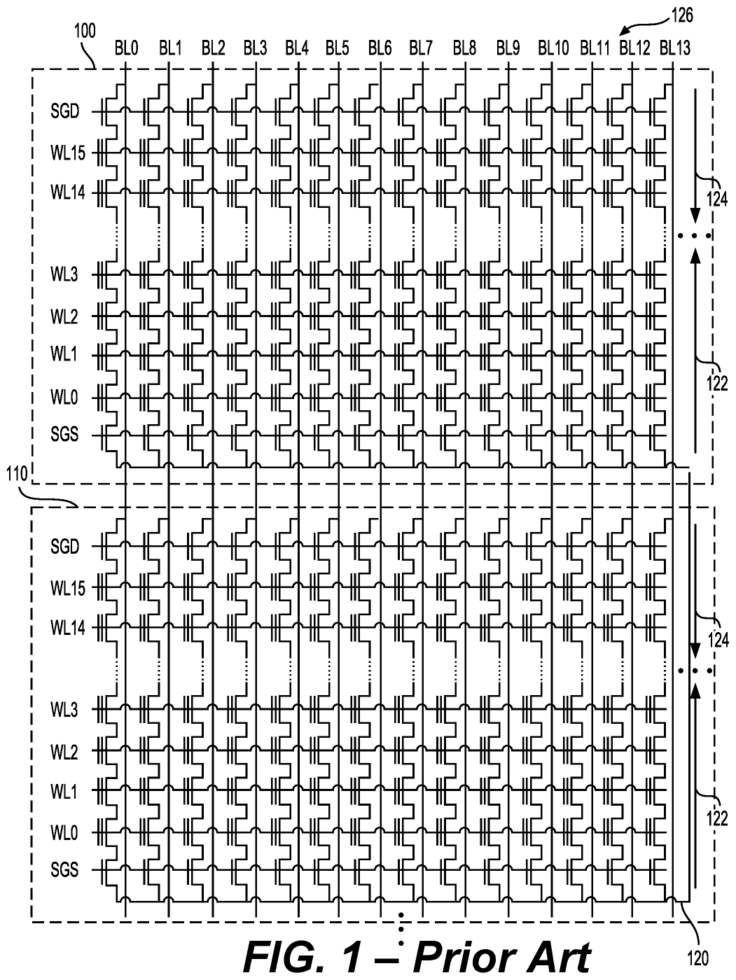

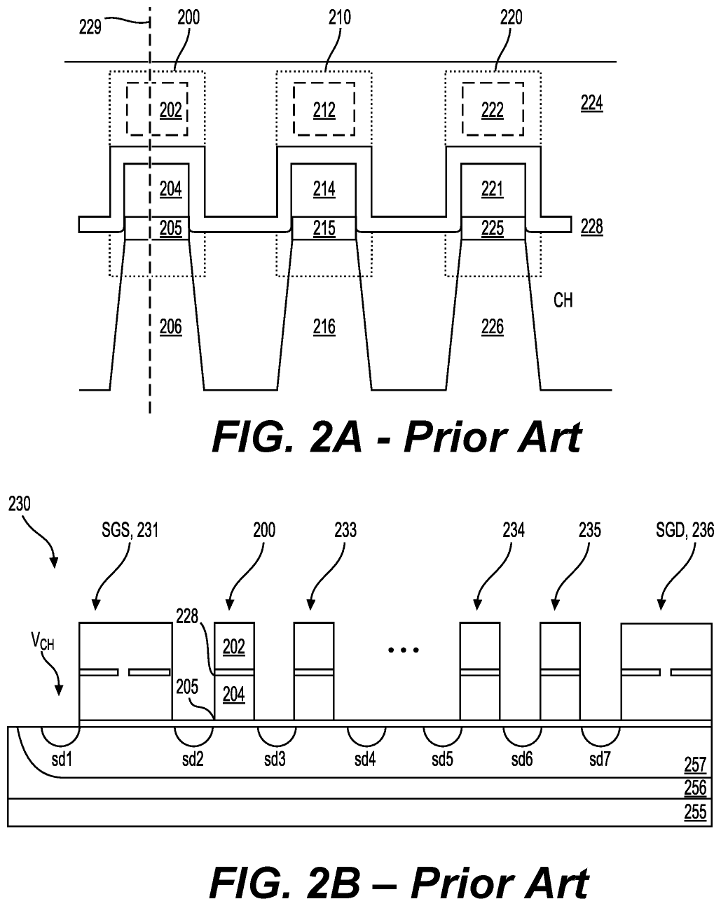

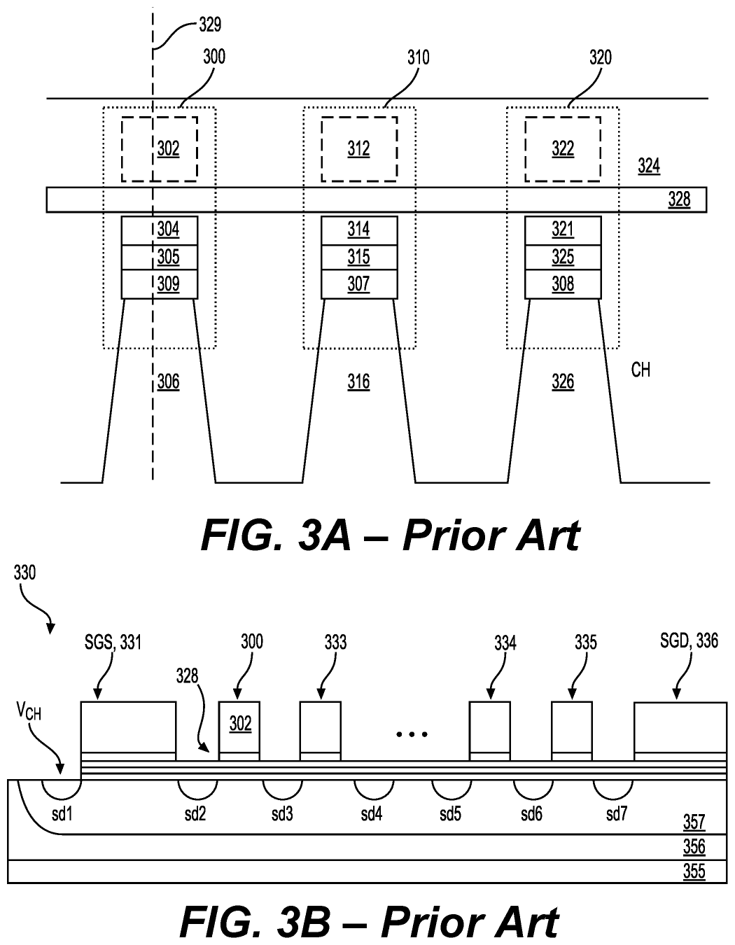

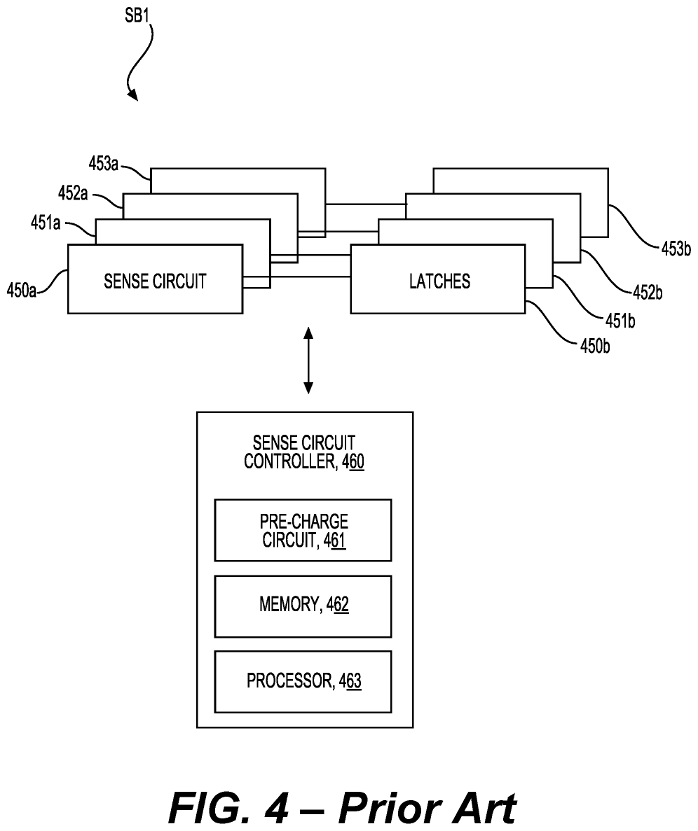

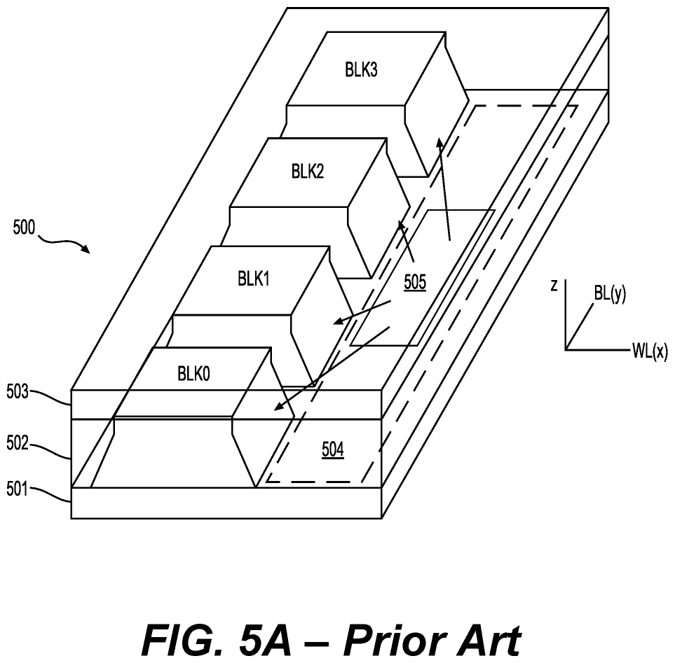

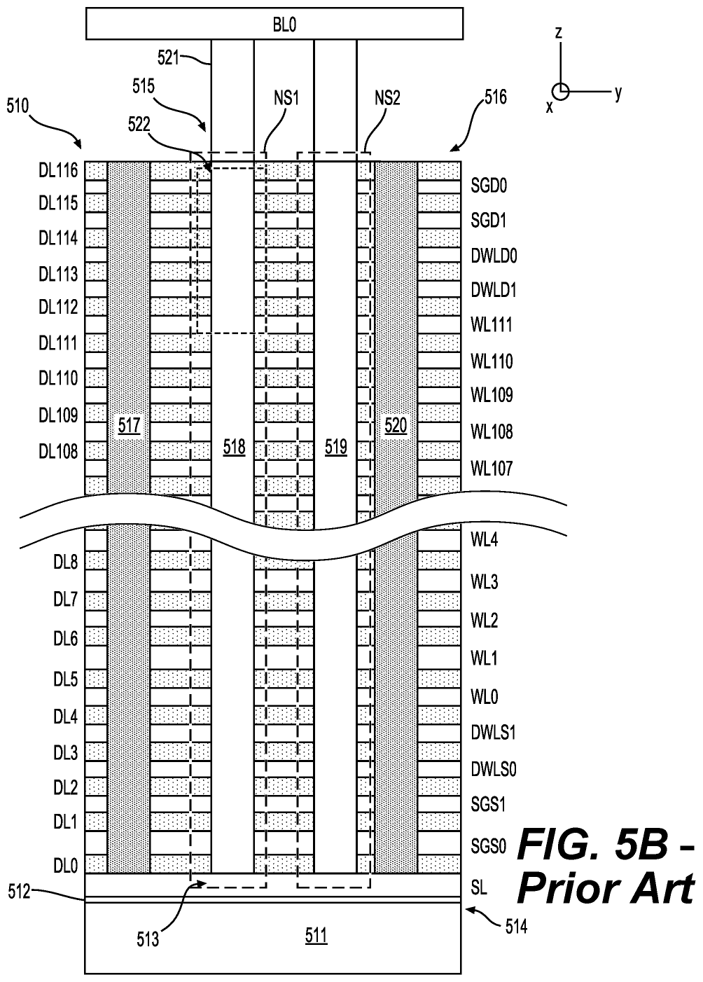

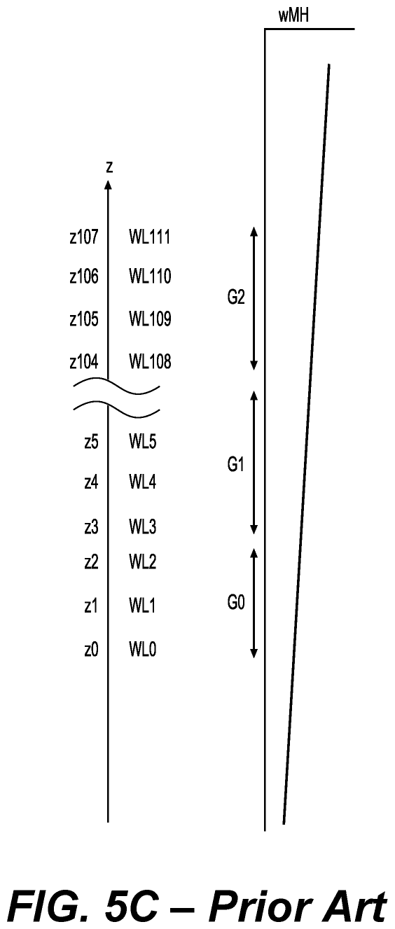

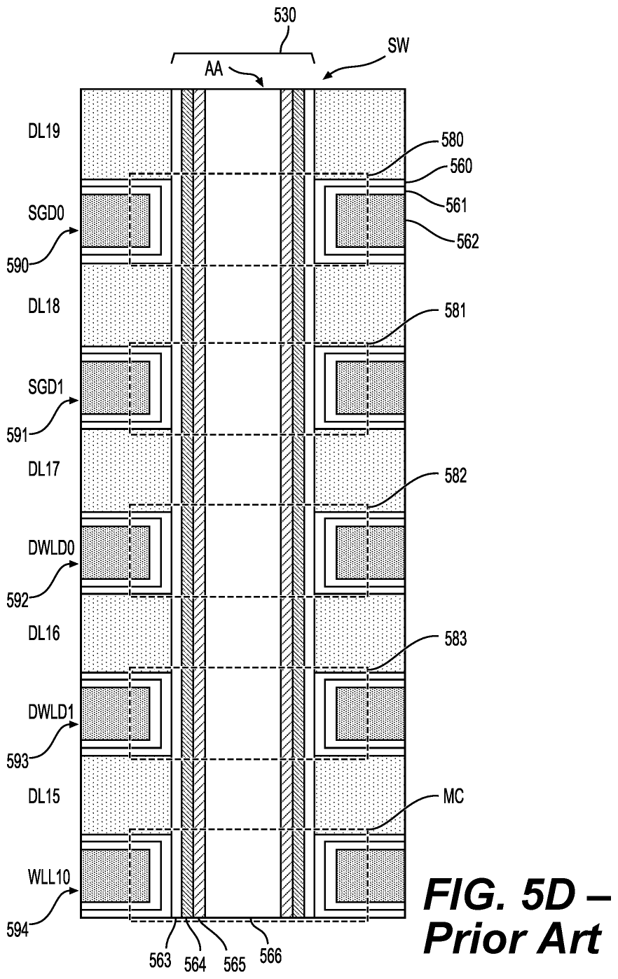

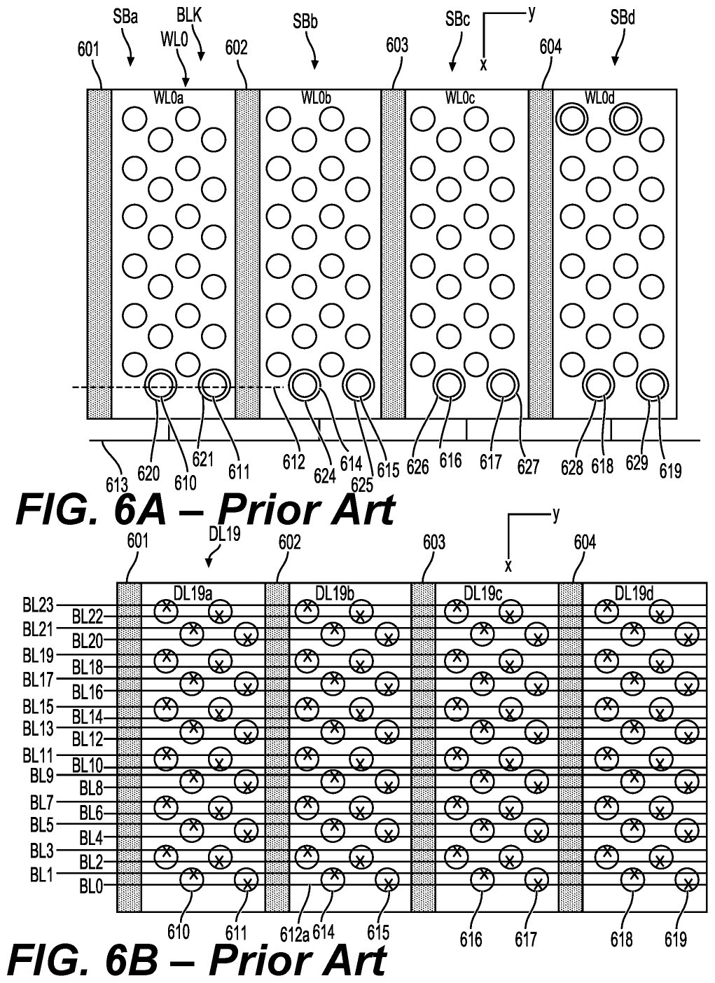

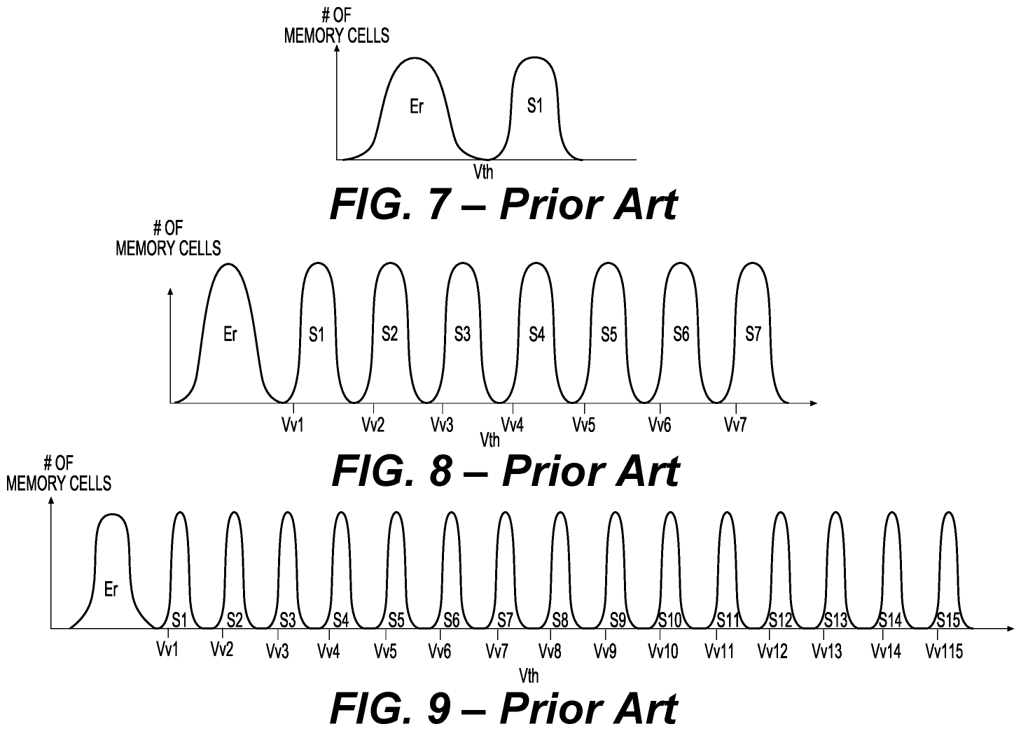

### DESCRIPTION OF THE ENABLING EMBODIMENTS

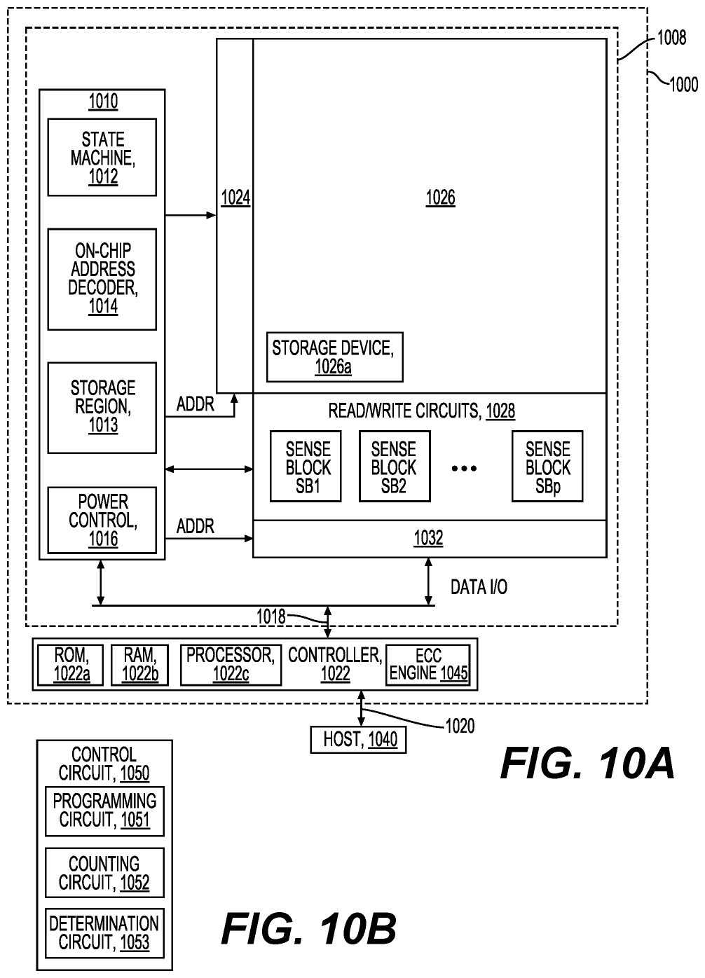

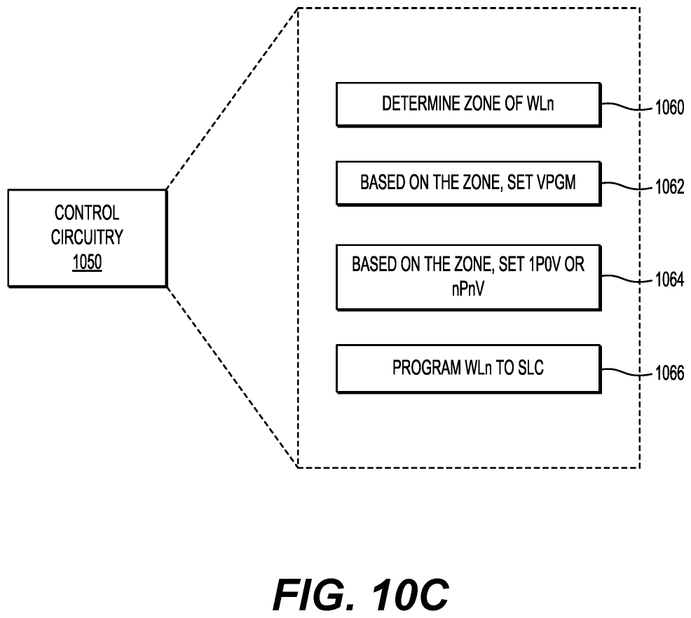

FIG. 10A is a block diagram of an example memory device 1000 that is configured to operate according to the programming techniques of the present disclosure. The memory die 1008 includes a memory structure 1026 of memory cells, such as an array of memory cells, control circuitry 1010, and read/write circuits 1028. The memory structure 1026 is addressable by word lines via a row decoder 1024 and by bit lines via a column decoder 1032. The read/write circuits 1028 include multiple sense blocks SB1, SB2, . . . SBp (sensing circuitry) and allow a page of memory cells to be read or programmed in parallel. Typically, a controller 1022 is included in the same memory device 1000 (e.g., a removable storage card) as the one or more memory die 1008. Commands and data are transferred between the host 1040 and controller 1022 via a data bus 1020, and between the controller and the one or more memory die 1008 via lines 1018.

The memory structure 1026 can be two-dimensional or three-dimensional. The memory structure 1026 may comprise one or more array of memory cells including a three-dimensional array. The memory structure 1026 may comprise a monolithic three-dimensional memory structure in which multiple memory levels are formed above (and not in) a single substrate, such as a wafer, with no intervening substrates. The memory structure 1026 may comprise any type of non-volatile memory that is monolithically formed in one or more physical levels of arrays of memory cells having an active area disposed above a silicon substrate. The memory structure 1026 may be in a non-volatile memory device having circuitry associated with the operation of the memory cells, whether the associated circuitry is above or within the substrate.

The control circuitry 1010 cooperates with the read/write circuits 1028 to perform memory operations on the memory structure 1026, and includes a state machine 1012, an on-chip address decoder 1014, and a power control module 1016. The state machine 1012 provides chip-level control of memory operations. As discussed in further detail below and illustrated in FIG. 10C, the control circuitry 1010 is configured to operate the memory device 1000 according to program techniques that allow for a low hSLC ratio with improved uniformity among the word lines through a zone based adaptive VPGM and/or programming pulse scheme. According to these techniques, at step 1060, the control circuitry 1050 determines a zone of a selected word line WLn within a hybrid memory block (discussed in further detail below). Based on the determination of the zone, at step 1062, the control circuitry 1050 sets an SLC programming voltage VPGM. Based on the determination of the zone, at step 1064, the control circuitry 1050 sets a programming scheme, e.g., 1P0V or 2P1V. At step 1066, the control circuitry 1050 programs the memory cells of the selected word line WLn to SLC. These operations are discussed in further detail below.

A storage region 1013 may, for example, be provided for programming parameters. The programming parameters may include a program voltage, a program voltage bias, position parameters indicating positions of memory cells, contact line connector thickness parameters, a verify voltage, and/or the like. The position parameters may indicate a position of a memory cell within the entire array of NAND strings, a position of a memory cell as being within a particular NAND string group, a position of a memory cell on a particular plane, and/or the like. The contact line connector thickness parameters may indicate a thickness of a contact line connector, a substrate or material that the contact line connector is comprised of, and/or the like.

The on-chip address decoder 1014 provides an address interface that is used by the host or a memory controller to determine the hardware address used by the decoders 1024 and 1032. The power control module 1016 controls the power and voltages supplied to the word lines and bit lines during memory operations. It can include drivers for word lines, SGS and SGD transistors, and source lines. The sense blocks can include bit line drivers, in one approach. An SGS transistor is a select gate transistor at a source end of a NAND string, and an SGD transistor is a select gate transistor at a drain end of a NAND string.

In some embodiments, some of the components can be combined. In various designs, one or more of the components (alone or in combination), other than memory structure 1026, can be thought of as at least one control circuit which is configured to perform the actions described herein. For example, a control circuit may include any one of, or a combination of, control circuitry 1010, state machine 1012, decoders 1014/1032, power control module 1016, sense blocks SBb, SB2, . . . SBp, read/write circuits 1028, controller 1022, and so forth.

The control circuits can include a programming circuit configured to perform a program and verify operation for one set of memory cells, wherein the one set of memory cells comprises memory cells assigned to represent one data state among a plurality of data states and memory cells assigned to represent another data state among the plurality of data states; the program and verify operation comprising a plurality of program and verify iterations; and in each program and verify iteration, the programming circuit performs programming for the one selected word line after which the programming circuit applies a verification signal to the selected word line. The control circuits can also include a counting circuit configured to obtain a count of memory cells which pass a verify test for the one data state. The control circuits can also include a determination circuit configured to determine, based on an amount by which the count exceeds a threshold, if a programming operation is completed. For example, FIG. 10B is a block diagram of an example control circuit 1050 which comprises a programming circuit 1051, a counting circuit 1052, and a determination circuit 1053.

The off-chip controller 1022 may comprise a processor 1022c, storage devices (memory) such as ROM 1022a and RAM 1022b and an error-correction code (ECC) engine 1045. The ECC engine can correct a number of read errors which are caused when the upper tail of a Vth distribution becomes too high. However, uncorrectable errors may exist in some cases. The techniques provided herein reduce the likelihood of uncorrectable errors.

The storage device(s) 1022a, 1022b comprise, code such as a set of instructions, and the processor 1022c is operable to execute the set of instructions to provide the functionality described herein. Alternately or additionally, the processor 1022c can access code from a storage device 1026a of the memory structure 1026, such as a reserved area of memory cells in one or more word lines. For example, code can be used by the controller 1022 to access the memory structure 1026 such as for programming, read and erase operations. The code can include boot code and control code (e.g., set of instructions). The boot code is software that initializes the controller 1022 during a booting or startup process and enables the controller 1022 to access the memory structure 1026. The code can be used by the controller 1022 to control one or more memory structures 1026. Upon being powered up, the processor 1022c fetches the boot code from the ROM 1022a or storage device 1026a for execution, and the boot code initializes the system components and loads the control code into the RAM 1022b. Once the control code is loaded into the RAM 1022b, it is executed by the processor 1022c. The control code includes drivers to perform basic tasks such as controlling and allocating memory, prioritizing the processing of instructions, and controlling input and output ports.

Generally, the control code can include instructions to perform the functions described herein including the steps of the flowcharts discussed further below and provide the voltage waveforms including those discussed further below.

In one embodiment, the host is a computing device (e.g., laptop, desktop, smartphone, tablet, digital camera) that includes one or more processors, one or more processor readable storage devices (RAM, ROM, flash memory, hard disk drive, solid state memory) that store processor readable code (e.g., software) for programming the one or more processors to perform the methods described herein. The host may also include additional system memory, one or more input/output interfaces and/or one or more input/output devices in communication with the one or more processors.

Other types of non-volatile memory in addition to NAND flash memory can also be used.

Semiconductor memory devices include volatile memory devices, such as dynamic random access memory (“DRAM”) or static random access memory (“SRAM”) devices, non-volatile memory devices, such as resistive random access memory (“ReRAM”), electrically erasable programmable read only memory (“EEPROM”), flash memory (which can also be considered a subset of EEPROM), ferroelectric random access memory (“FRAM”), and magnetoresistive random access memory (“MRAM”), and other semiconductor elements capable of storing information. Each type of memory device may have different configurations. For example, flash memory devices may be configured in a NAND or a NOR configuration.

The memory devices can be formed from passive and/or active elements, in any combinations. By way of non-limiting example, passive semiconductor memory elements include ReRAM device elements, which in some embodiments include a resistivity switching storage element, such as an anti-fuse or phase change material, and optionally a steering element, such as a diode or transistor. Further by way of non-limiting example, active semiconductor memory elements include EEPROM and flash memory device elements, which in some embodiments include elements containing a charge storage region, such as a floating gate, conductive nanoparticles, or a charge storage dielectric material.

Multiple memory elements may be configured so that they are connected in series or so that each element is individually accessible. By way of non-limiting example, flash memory devices in a NAND configuration (NAND memory) typically contain memory elements connected in series. A NAND string is an example of a set of series-connected transistors comprising memory cells and SG transistors.

A NAND memory array may be configured so that the array is composed of multiple memory strings in which a string is composed of multiple memory elements sharing a single bit line and accessed as a group. Alternatively, memory elements may be configured so that each element is individually accessible, e.g., a NOR memory array. NAND and NOR memory configurations are examples, and memory elements may be otherwise configured. The semiconductor memory elements located within and/or over a substrate may be arranged in two or three dimensions, such as a two-dimensional memory structure or a three-dimensional memory structure.

In a two-dimensional memory structure, the semiconductor memory elements are arranged in a single plane or a single memory device level. Typically, in a two-dimensional memory structure, memory elements are arranged in a plane (e.g., in an x-y direction plane) which extends substantially parallel to a major surface of a substrate that supports the memory elements. The substrate may be a wafer over or in which the layer of the memory elements is formed or it may be a carrier substrate which is attached to the memory elements after they are formed. As a non-limiting example, the substrate may include a semiconductor such as silicon.

The memory elements may be arranged in the single memory device level in an ordered array, such as in a plurality of rows and/or columns. However, the memory elements may be arrayed in non-regular or non-orthogonal configurations. The memory elements may each have two or more electrodes or contact lines, such as bit lines and word lines.

A three-dimensional memory array is arranged so that memory elements occupy multiple planes or multiple memory device levels, thereby forming a structure in three dimensions (i.e., in the x, y and z directions, where the z-direction is substantially perpendicular and the x- and y-directions are substantially parallel to the major surface of the substrate).

As a non-limiting example, a three-dimensional memory structure may be vertically arranged as a stack of multiple two-dimensional memory device levels. As another non-limiting example, a three-dimensional memory array may be arranged as multiple vertical columns (e.g., columns extending substantially perpendicular to the major surface of the substrate, i.e., in the y direction) with each column having multiple memory elements. The columns may be arranged in a two-dimensional configuration, e.g., in an x-y plane, resulting in a three-dimensional arrangement of memory elements with elements on multiple vertically stacked memory planes. Other configurations of memory elements in three dimensions can also constitute a three-dimensional memory array.

By way of non-limiting example, in a three-dimensional array of NAND strings, the memory elements may be coupled together to form a NAND string within a single horizontal (e.g., x-y) memory device level. Alternatively, the memory elements may be coupled together to form a vertical NAND string that traverses across multiple horizontal memory device levels. Other three-dimensional configurations can be envisioned wherein some NAND strings contain memory elements in a single memory level while other strings contain memory elements which span through multiple memory levels. Three-dimensional memory arrays may also be designed in a NOR configuration and in a ReRAM configuration.

Typically, in a monolithic three-dimensional memory array, one or more memory device levels are formed above a single substrate. Optionally, the monolithic three-dimensional memory array may also have one or more memory layers at least partially within the single substrate. As a non-limiting example, the substrate may include a semiconductor such as silicon. In a monolithic three-dimensional array, the layers constituting each memory device level of the array are typically formed on the layers of the underlying memory device levels of the array. However, layers of adjacent memory device levels of a monolithic three-dimensional memory array may be shared or have intervening layers between memory device levels.

Then again, two-dimensional arrays may be formed separately and then packaged together to form a non-monolithic memory device having multiple layers of memory. For example, non-monolithic stacked memories can be constructed by forming memory levels on separate substrates and then stacking the memory levels atop each other. The substrates may be thinned or removed from the memory device levels before stacking, but as the memory device levels are initially formed over separate substrates, the resulting memory arrays are not monolithic three-dimensional memory arrays. Further, multiple two-dimensional memory arrays or three-dimensional memory arrays (monolithic or non-monolithic) may be formed on separate chips and then packaged together to form a stacked-chip memory device.

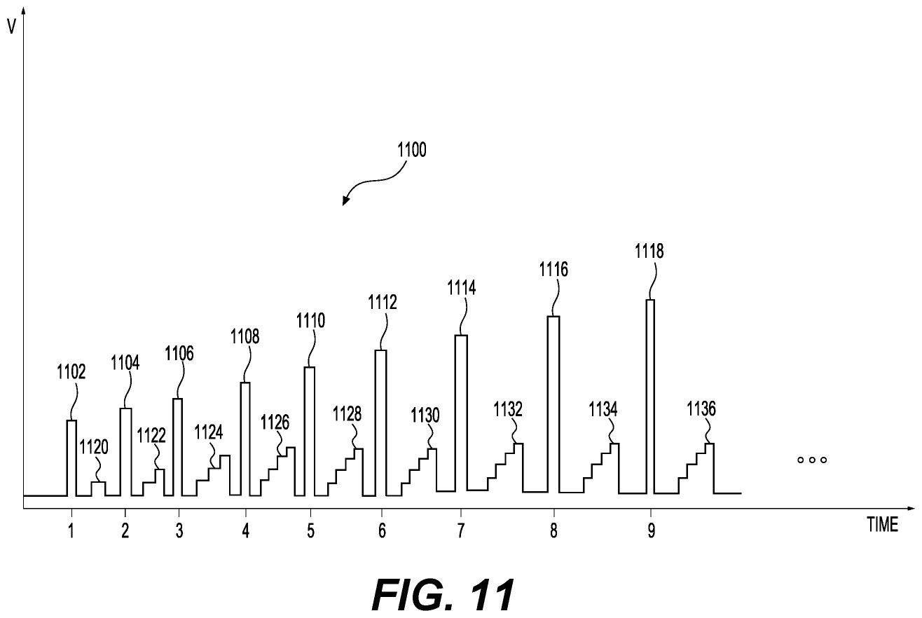

Programming memory cells of a selected word line to SLC (one bit of data per memory cell) may start with the memory cells in the erased data state and include one programming pulse and zero verify operations (1P0V) or may include two programming pulses and one or two verify operations (2P1V or 2P2V). On the other hand, programming the memory cells of a selected word line to retain multiple bits per memory cell (for example, MLC, TLC, or QLC) starts with the memory cells being in the erased data state and includes a plurality of program loops, each of which includes both a programming pulse and a verify operation. FIG. 11 depicts a waveform 1100 of the voltages applied to a selected word line during an example memory cell programming operation for programming the memory cells of the selected word line to a greater number of bits per memory cell (e.g., TLC or QLC). As depicted, each program loop includes a programming pulse VPGM and one or more verify pulses, depending on which data states are being programmed in a particular program loop. A square waveform is depicted for each pulse for simplicity; however, other shapes are possible, such as a multilevel shape or a ramped shape.

Incremental Step Pulse Programming (ISPP) is used in this example pulse train, which means that the VPGM pulse amplitude steps up, or increases, in each successive program loop. More specifically, the pulse train includes VPGM pulses that increase stepwise in amplitude with each successive program loop by a fixed step size (dVPGM). A new pulse train starts with an initial VPGM pulse level VPGMU and ends at a final VPGM pulse level, which does not exceed a maximum allowed level. The example pulse train 1100 includes a series of VPGM pulses 1101-1115 that are applied to a selected word line that includes a set of non-volatile memory cells. One or more verify voltage pulses 1116-1129 are provided after each VPGM pulse as an example, based on the target data states which are being verified in the program loop. The verify voltages correspond with voltages Vv1-Vv7 shown in FIG. 8 or Vv1-Vv15 shown in FIG. 9. Concurrent with the application of the verify voltages, a sensing operation can determine whether a particular memory cell in the selected word line has a threshold voltage Vt above the verify voltage associated with its intended data state by sensing a current through the memory cell. If the current is relatively high during sensing, this indicates that the memory cell is in a conductive state, such that its threshold voltage Vt is less than the verify voltage. If the current is relatively low during sensing, this indicates that the memory cell is in a non-conductive state, such that its threshold voltage Vt is above the verify voltage. If the memory cell passes verify, programming of that memory cell is completed and further programming of that memory cell is inhibited for all remaining program loops by applying an inhibit voltage to a bit line coupled with the memory cell concurrent with the VPGM pulse. Programming proceeds until all memory cells pass verify for their intended data states, in which case, programming passes, or until a predetermined maximum number of program loops is exceeded, in which case, programming fails. In some embodiments, the memory cells of a word line can be divided into a series of string groups, or simply strings, that can be programmed independently of one another, and programming can commence from one string to another across the word line before proceeding to the next word line in the memory block.

An erase operation involves transitioning the memory cells from their respective programmed data states to the erased state. During the erase operation, it is desired to lower the threshold voltages Vth of the memory cells below an erase-verify level that represents an upper bound of the erased data state. An erase operation can include a number of erase loops, each including an erase operation followed by a verify operation. The erase operation is typically performed on a memory block level rather than a word line level, i.e., one entire memory block at a time.

In the erase operation of an erase loop, the control circuitry is configured to apply an erase voltage VERA is applied to the strings of the memory block while applying a very low voltage (for example, zero Volts) to the word lines of the memory block to provide a positive channel-to-gate voltage for the memory cells of the block to drive electrons out of the charge storing materials of the memory cells, thereby reducing the threshold voltages Vth of the memory cells. In the verify portion, a verify voltage is applied to the control gates of the memory cells and sensing circuitry is used to sense currents in the NAND strings to determine if the memory cells have been sufficiently erased. If an insufficient number of memory cells have been sufficiently erased, then this process is repeated in one or more subsequent erase loops until the erase verify operation passes. Similar to ISPP programming, as described above, the magnitude of the erase pulse can increase between erase loops.

In the exemplary embodiment, the memory device is configured to operate the memory blocks in multiple storage scheme modes, e.g., an SLC mode and a TLC mode or an SLC mode and a QLC mode. This allows the memory device to initially write data to memory blocks operating in an SLC mode, which offers high performance, and then in a background operation when performance is not important, the memory device can re-program that data from the SLC format to a multi-bit per memory cell format (for example, QLC) for long-term storage.

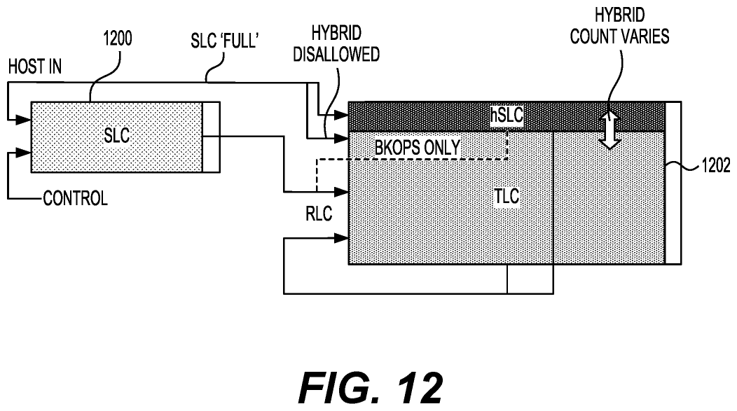

Turning now to FIG. 12, in the exemplary embodiment, the memory device includes a plurality memory blocks that are dedicated to high performance SLC operation and are hereinafter referred to as “dedicated SLC” blocks 1200. The dedicated SLC blocks 1200 can only write data in the SLC format. The memory device also includes a plurality of hybrid memory blocks 1202 that can operate in a hybrid SLC (“hSLC”) mode or in a QLC (or TLC in some embodiments) mode. The hybrid memory blocks 1202 can write data in either the SLC format or the QLC (or TLC) format.

During a write operation, if adequate space exists in the dedicated SLC blocks 1200 to accommodate the user's data, then the data will be programmed at high performance to only the dedicated SLC blocks 1200, and the data will later, in a background operation, be folded into the hybrid blocks 1202 in QLC format for long term storage at high density. On the other hand, if the dedicated SLC blocks 1200 become full during the write operation and cannot accommodate additional data to be written, one or more of the hybrid blocks 1202 can be operated in the hSLC mode to complete the write operation at high performance. During a background operation, the data can then be folded from the hybrid blocks 1202 operating in the hSLC mode to other hybrid blocks 1202 operating in the TLC mode for long term storage at high density.

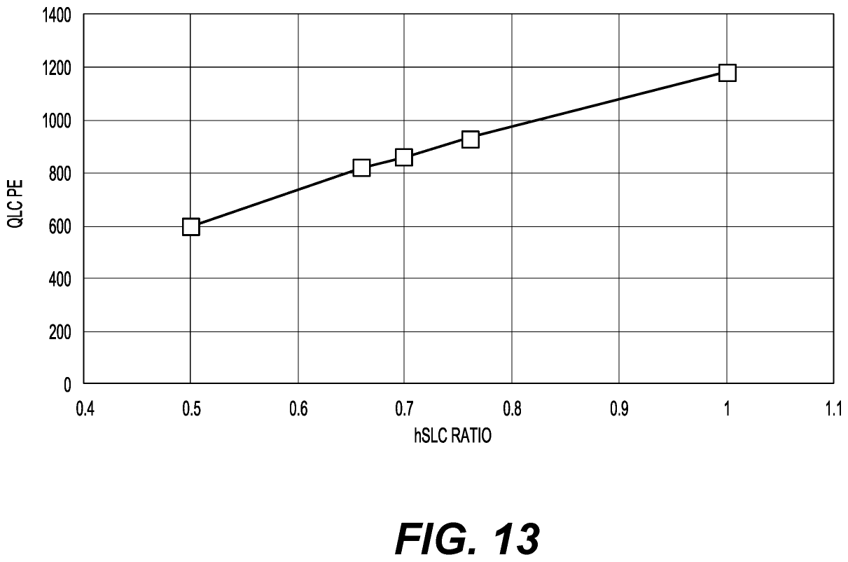

FIG. 13 depicts a plot of the hSLC ratio versus the number of QLC program erase (PE) cycles needed to reach a target total amount of data written over the lifetime of a memory device, e.g., one hundred and fifty terabytes written (150 TBW). The hSLC ratio is defined by the endurance of either TLC or QLC programming to hSLC programming with the same threshold voltage Vt margin loss. As illustrated, the greater the hSLC ratio, the more QLC PE cycles are necessary to write this target amount of data, i.e., more programming in the QLC mode and less programming in the SLC mode. Therefore, if the hSLC ratio is set at a low amount, then the hybrid memory blocks do not have to experience as many PE cycles in the QLC operating mode to write a target amount of data written over its operating life, thereby reducing the QLC endurance requirement. This is one benefit of operating the memory device with a low hSLC ratio.

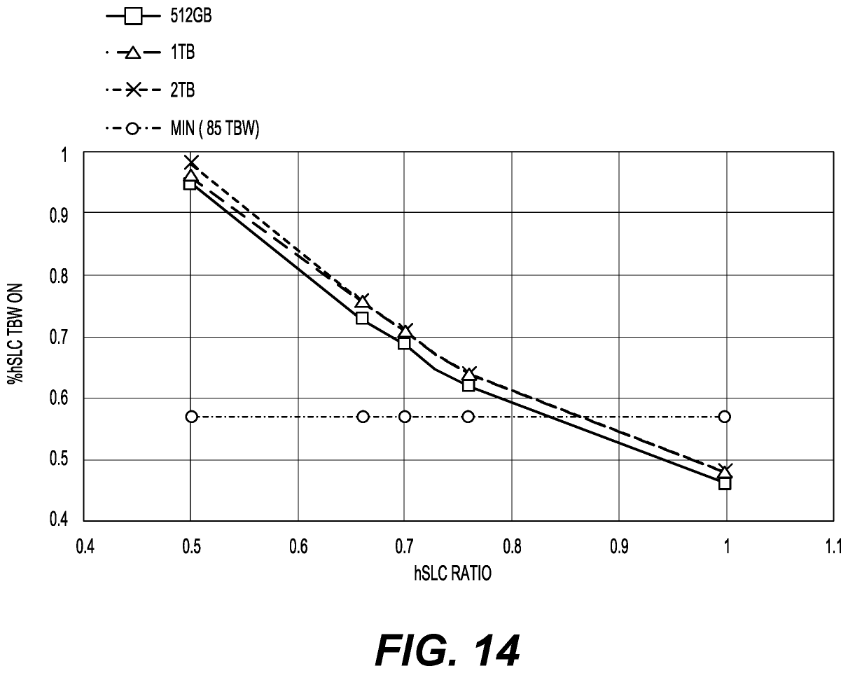

FIG. 14 depicts a plot of the percent that the hSLC mode is turned on in the hybrid blocks versus the hSLC ratio to write different amounts of data to the memory device. As illustrated, the lower the hSLC ratio, the higher percentage that the hSLC mode can be turned on, thereby improving the performance of the memory device. In other words, a low hSLC ratio also allows for improved overall performance during the operating life of the memory device. This is another benefit of operating the memory device with a low hSLC ratio.

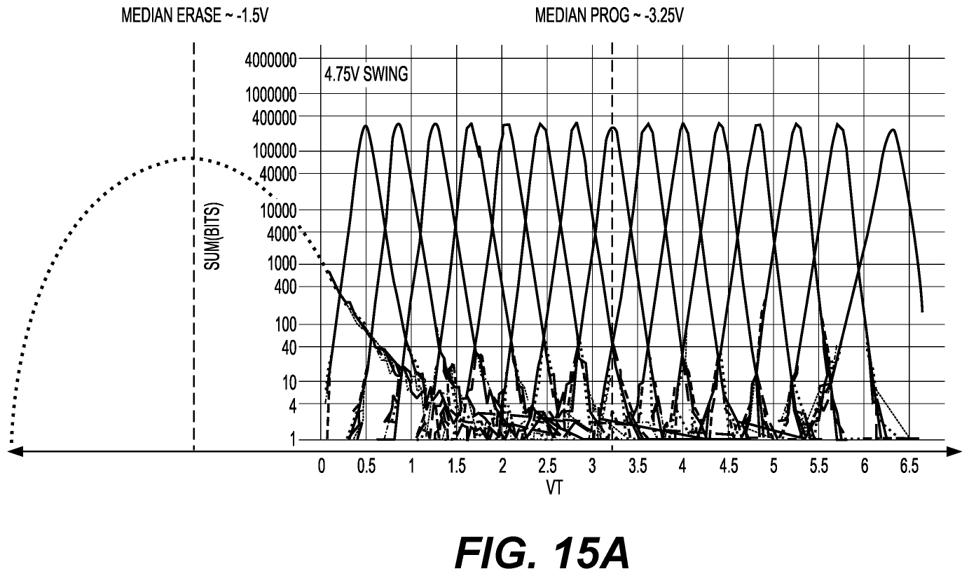

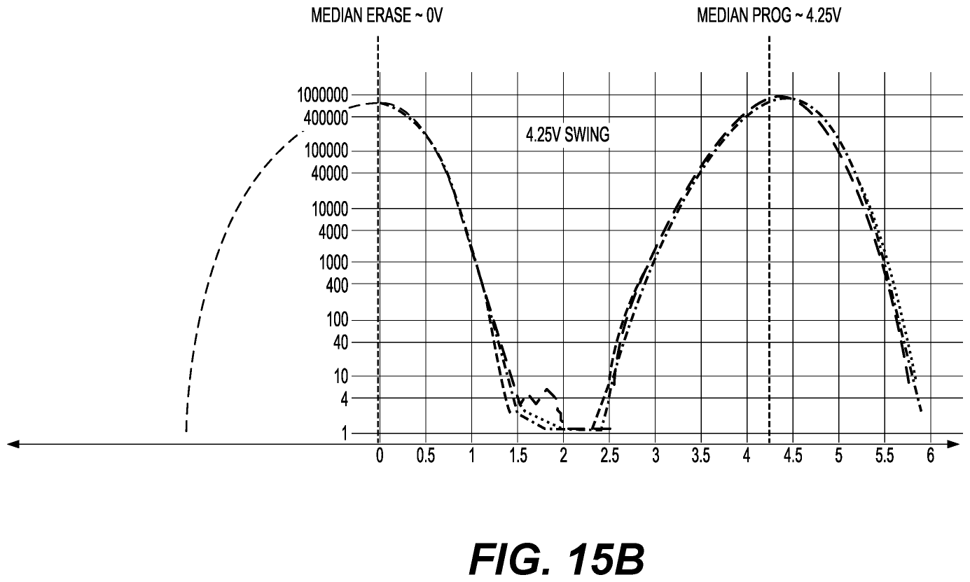

Turning now to FIGS. 15A and 15B, the median erased threshold voltage and the median programmed threshold voltage of a page of memory cells programmed to QLC (FIG. 15A) are different than a page of memory cells programmed to SLC (FIG. 15B). For example, in the exemplary embodiment, the median erase voltage is −1.5V for QLC and is 0 V for SLC. The difference between the median erase voltages for QLC and SLC is because a lower (more negative) erase verify voltage is used during the QLC erase than during the SLC erase. The median programmed voltage is 3.25 V for QLC and is 4.25 V for SLC.

The amount of endurance damage a memory cell receives during operation is largely based on the threshold voltage swing between its programmed and erased conditions. In the example of FIG. 15A, the average swing voltage of a memory cell between the QLC erased state and one of the QLC programmed states is approximately 4.75 V; and in the example of FIG. 15B, the average swing voltage of a memory cell between the SLC erased state and the SLC programmed state is approximately 4.25 V. However, transitioning operation of the hybrid blocks between the QLC and SLC modes can result in much greater swing voltages. For example, performing a QLC erase on memory cells programmed to SLC can result in a 5.75 V swing, and performing an SLC program operation on memory cells erased using a QLC erase can also result in a 5.75 V swing.

According to an aspect of the present disclosure, when a hybrid memory block transitions from QLC operation to SLC operation, an SLC erase operation using an SLC erase verify voltage is employed such that the voltage swing that the memory cells in that hybrid memory block experience is reduced. In the example depicted in FIGS. 15A and 15B, by erasing memory cells programmed to QLC using an SLC erase scheme, the average voltage swing is approximately 3.25 V versus 4.75 when using a QLC erase scheme. Additionally, when programming the memory cells from the average SLC erase voltage to the average SLC programmed voltage, the voltage swing is approximately 4.25 V rather than 5.75 V when programming from the average QLC erase voltage to the average SLC programmed voltage. Both of these effects reduce the endurance damage those memory cells experience during the erase operation and the ensuing programming operation. Therefore, if it is determined that the next host write demand is going to benefit from a hybrid memory block that is currently programmed to QLC being transitioned to hSLC operation, then an SLC erase operation using an SLC erase verify voltage is employed.

According to another aspect of the present disclosure, the operating parameters when programming and erasing the memory cells in the dedicated SLC blocks are different than the operating parameters when programming the memory cells in the hybrid blocks when the hybrid blocks are operating in the hSLC mode. Specifically, a “gentle program” operation is used when programming the memory cells in a hybrid memory block. The gentle program operation includes the application of a lower starting programming voltage (VPGMSLC) as compared to the “normal program” operation of the dedicated SLC block. Also, a “gentle erase” operation is used when performing an SLC erase on a hybrid memory block. The gentle erase includes a lower starting erase voltage (VERA_SLC) as compared to the “normal erase” operation of the dedicated SLC blocks and a greater erase verify voltage (DVCG_EVFY_SLC) as compared to the normal erase operation. Many other operating parameters are shared in the hybrid blocks during operation in both the hSLC and the QLC modes.

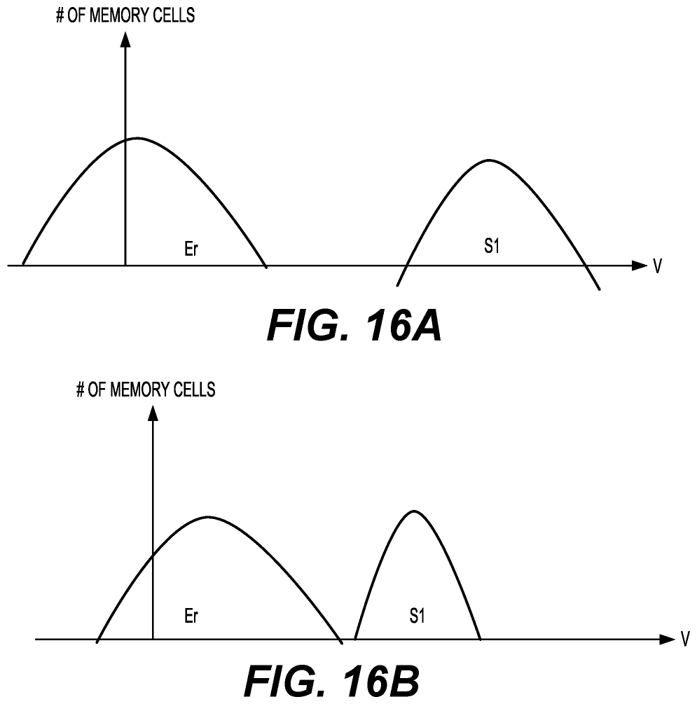

FIG. 16A illustrates the threshold voltage distribution of a page of memory cells erased using a normal erase operation and then programmed using a normal program operation, and FIG. 16B illustrates the threshold voltage distribution of a page of memory cells erasing using a gentle erase operation and then programmed using a gentle program operation. As illustrated, the gentle erase operation yields a higher erased data state curve Er and a lower programmed data state curve S1. However, an adequate gap is present between the erased data state curve Er and the programmed data state curve S1 to allow the control circuitry of the memory device to discern between the two data states during a read operation. By conducting the gentle erase and the gentle program operation on the hybrid blocks when they are operating in the hSLC mode, the endurance damage to these memory cells is further reduced and the threshold voltage Vt margin is improved, thereby allowing the hSLC ratio to be further reduced.

Due mostly to the construction of the memory holes, in many memory blocks, there is a wide variation in threshold voltage Vt margin from word line to word line because the memory cells in different areas of the memory block are subjected to differing degrees of endurance damage. This variation is particularly pronounced between the word lines aligned with the upper memory holes and the word lines aligned with the lower memory holes. The word lines in a memory block that experience similar damage can be grouped together in zones.

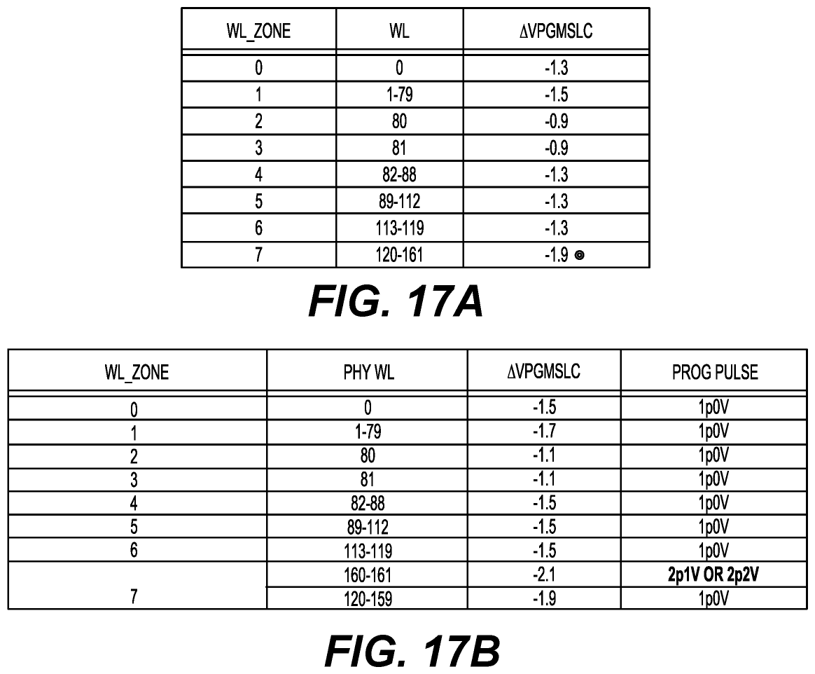

According to another aspect of the present disclosure, a uniform hSLC ratio is achieved through a word line zone adaptive programming voltage VPGM_SLC and/or by using different programming schemes for different word lines, e.g., 1P0V or nPnV. For example, if the hSLC ratio is above a threshold, then during programming of a word line, a determination is made on which zone the word line is located in and what the starting programming voltage VPGM_SLC should be. FIG. 17A provides a table with example starting program voltages VPGM_SLC that includes one hundred and sixty-one (161) word lines that are divided into eight (8) zones to achieve a generally uniform hSLC ratio across an example memory block. The voltages listed in this table are the differences from the starting programming voltage VPGM_SLC that is used when programming the memory cells in one of the dedicated SLC blocks. For example, if a selected word line is in Zone 1 of a hybrid memory block that is operating in the hSLC mode, then the starting programming voltage is 1.5 V less than the starting programming voltage VPGM_SLC that is used in the dedicated SLC blocks, i.e., VPGM_SLC-1.5 V. In some embodiments, the memory block may include either more or fewer than eight zones.

In some zones (for example, Zone 7 in the example of FIG. 17B), the starting programing voltage VPGM_SLC may be so low that programming with a 1P0V programming operation may result in an unacceptably low threshold voltage Vt margin. In such cases, the control circuitry programs the memory cells of those word lines using a multiple program loop operation including at least one verify pulse, e.g., 2P1V or 2P2V. Adding an additional program pulse increases the lower tail of the programmed data state, thereby increasing the Vt margin and protecting the word line from read failure while still protecting the memory cells in these word lines from endurance damage. In some embodiments, the adaptive starting programming voltage VPGMSLC and/or the programming scheme can be on a string-by-string basis within each word line. For example, in a hybrid block with four strings (String_0 through String_3), the programming scheme can be 1P0V for String_0, String_1, and String_3 and can be 2P1V when programming String_2.

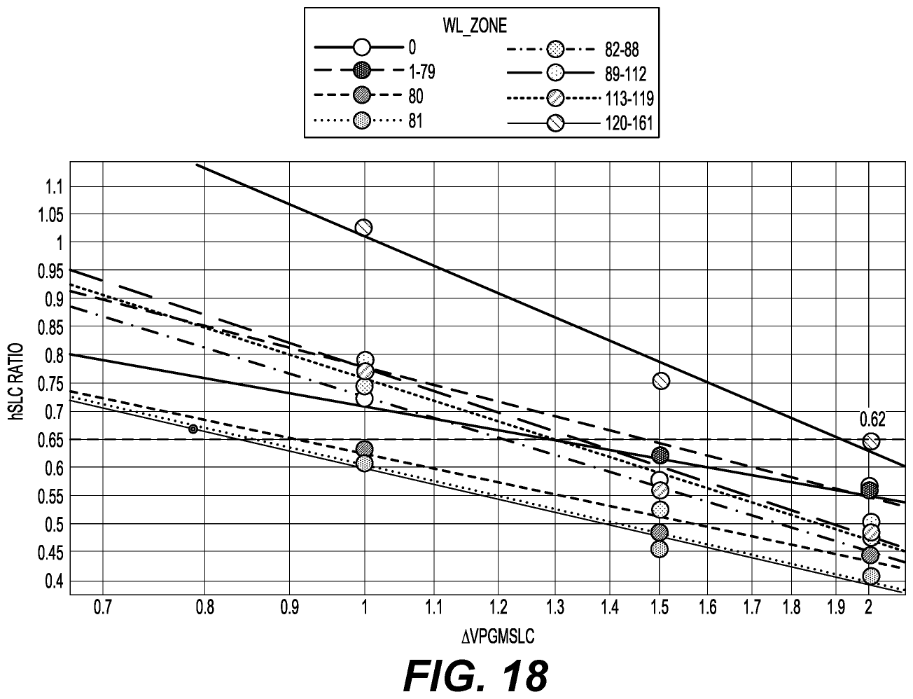

FIG. 18 depicts a plot of hSLC ratio versus the magnitude of AVPGMSLC (the difference between VPGM in the hybrid memory blocks and in the dedicated SLC memory blocks). As illustrated, the higher the magnitude of AVPGMSLC (i.e., the lower the VPGM), the lower the hSLC ratio becomes. If a target hSLC ratio is desired (for example, 0.65), the AVPGMSLC can be selected appropriately for each word line zone. By this process, a more uniform hSLC ratio within the hybrid block is achieved.

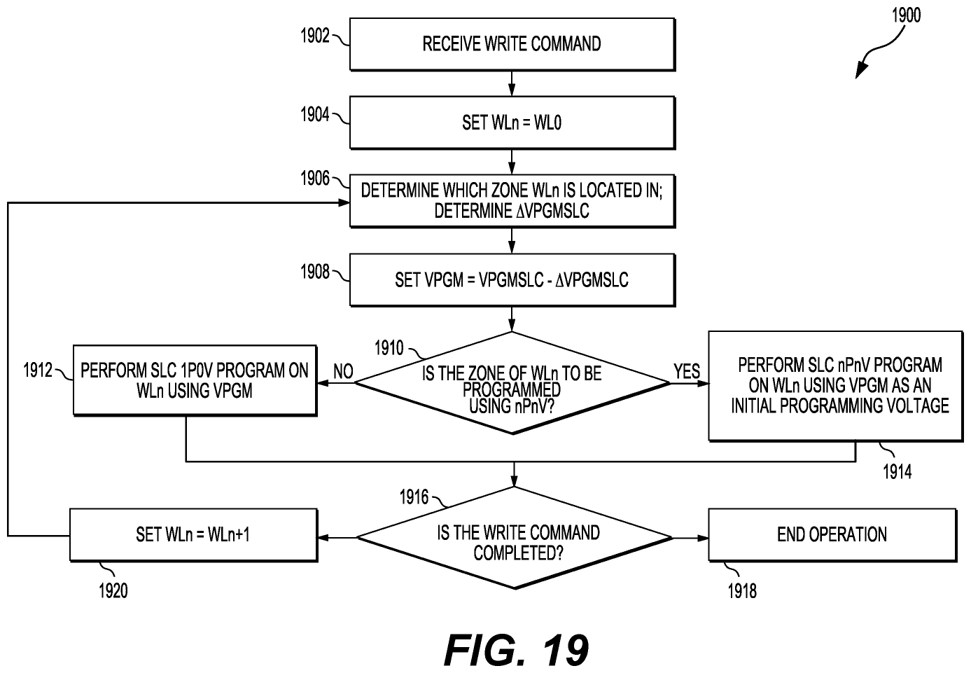

Turning now to FIG. 19, a flow chart 1900 depicting the steps of programming the word lines of a hybrid block according to an exemplary embodiment is provided. At step 1902, a write command is received by the control circuitry of the memory device and a selected hybrid block is designated. At step 1904, a selected word line WLn is set to a first word line to be programmed, e.g., WL0. In some embodiments the first word line could be a different word line, such as a last word line in the selected memory block in the case of reverse order programming or a word line between the first and last word lines in the selected memory block.

At step 1906, the control circuitry determines which zone the selected word line WLn is located in and references data stored in the memory device to determine AVPGMSLC for that zone. At step 1908, an initial programming voltage VPGM is set to VPGMSLC (the programming voltage for the dedicated SLC blocks) minus AVPGMSLC, i.e., VPGM=VPGM_SLC−ΔVPGMSLC.

At decision step 1910, it is determined if the zone of WLn is to be programmed using an nPnV (for example, 2P1V or 1P1V) programming operation. If the answer at decision step 1910 is “no,” then at step 1912, a 1P0V programming operation is performed on the selected word line to program the memory cells of the selected word line to SLC. If the answer at decision step 1910 is “yes,” then at step 1914, an nPnV programming operation is performed on the selected word line to program the memory cells of the selected word line to SLC.

Following either step 1912 or 1914, at decision step 1916, it is determined if the write command is completed. If the answer at decision step 1916 is “yes,” then at step 1918, the write operation is completed. If the answer at step 1916 is “no,” then at step 1920, the selected word line is incrementally advanced, e.g., WLn=WLn+1. In some embodiments, WLn may be set to WLn-1. The process then returns to step 1906.

Various terms are used herein to refer to particular system components. Different companies may refer to a same or similar component by different names and this description does not intend to distinguish between components that differ in name but not in function. To the extent that various functional units described in the following disclosure are referred to as “modules,” such a characterization is intended to not unduly restrict the range of potential implementation mechanisms. For example, a “module” could be implemented as a hardware circuit that includes customized very-large-scale integration (VLSI) circuits or gate arrays, or off-the-shelf semiconductors that include logic chips, transistors, or other discrete components. In a further example, a module may also be implemented in a programmable hardware device such as a field programmable gate array (FPGA), programmable array logic, a programmable logic device, or the like. Furthermore, a module may also, at least in part, be implemented by software executed by various types of processors. For example, a module may comprise a segment of executable code constituting one or more physical or logical blocks of computer instructions that translate into an object, process, or function. Also, it is not required that the executable portions of such a module be physically located together, but rather, may comprise disparate instructions that are stored in different locations and which, when executed together, comprise the identified module and achieve the stated purpose of that module. The executable code may comprise just a single instruction or a set of multiple instructions, as well as be distributed over different code segments, or among different programs, or across several memory devices, etc. In a software, or partial software, module implementation, the software portions may be stored on one or more computer-readable and/or executable storage media that include, but are not limited to, an electronic, magnetic, optical, electromagnetic, infrared, or semiconductor-based system, apparatus, or device, or any suitable combination thereof. In general, for purposes of the present disclosure, a computer-readable and/or executable storage medium may be comprised of any tangible and/or non-transitory medium that is capable of containing and/or storing a program for use by or in connection with an instruction execution system, apparatus, processor, or device.

Similarly, for the purposes of the present disclosure, the term “component” may be comprised of any tangible, physical, and non-transitory device. For example, a component may be in the form of a hardware logic circuit that is comprised of customized VLSI circuits, gate arrays, or other integrated circuits, or is comprised of off-the-shelf semiconductors that include logic chips, transistors, or other discrete components, or any other suitable mechanical and/or electronic devices. In addition, a component could also be implemented in programmable hardware devices such as field programmable gate arrays (FPGA), programmable array logic, programmable logic devices, etc. Furthermore, a component may be comprised of one or more silicon-based integrated circuit devices, such as chips, die, die planes, and packages, or other discrete electrical devices, in an electrical communication configuration with one or more other components via electrical conductors of, for example, a printed circuit board (PCB) or the like. Accordingly, a module, as defined above, may in certain embodiments, be embodied by or implemented as a component and, in some instances, the terms module and component may be used interchangeably.

Where the term “circuit” is used herein, it includes one or more electrical and/or electronic components that constitute one or more conductive pathways that allow for electrical current to flow. A circuit may be in the form of a closed-loop configuration or an open-loop configuration. In a closed-loop configuration, the circuit components may provide a return pathway for the electrical current. By contrast, in an open-looped configuration, the circuit components therein may still be regarded as forming a circuit despite not including a return pathway for the electrical current. For example, an integrated circuit is referred to as a circuit irrespective of whether the integrated circuit is coupled to ground (as a return pathway for the electrical current) or not. In certain exemplary embodiments, a circuit may comprise a set of integrated circuits, a sole integrated circuit, or a portion of an integrated circuit. For example, a circuit may include customized VLSI circuits, gate arrays, logic circuits, and/or other forms of integrated circuits, as well as may include off-the-shelf semiconductors such as logic chips, transistors, or other discrete devices. In a further example, a circuit may comprise one or more silicon-based integrated circuit devices, such as chips, die, die planes, and packages, or other discrete electrical devices, in an electrical communication configuration with one or more other components via electrical conductors of, for example, a printed circuit board (PCB). A circuit could also be implemented as a synthesized circuit with respect to a programmable hardware device such as a field programmable gate array (FPGA), programmable array logic, and/or programmable logic devices, etc. In other exemplary embodiments, a circuit may comprise a network of non-integrated electrical and/or electronic components (with or without integrated circuit devices). Accordingly, a module, as defined above, may in certain embodiments, be embodied by or implemented as a circuit.

It will be appreciated that example embodiments that are disclosed herein may be comprised of one or more microprocessors and particular stored computer program instructions that control the one or more microprocessors to implement, in conjunction with certain non-processor circuits and other elements, some, most, or all of the functions disclosed herein. Alternatively, some or all functions could be implemented by a state machine that has no stored program instructions, or in one or more application-specific integrated circuits (ASICs) or field-programmable gate arrays (FPGAs), in which each function or some combinations of certain of the functions are implemented as custom logic. A combination of these approaches may also be used. Further, references below to a “controller” shall be defined as comprising individual circuit components, an application-specific integrated circuit (ASIC), a microcontroller with controlling software, a digital signal processor (DSP), a field programmable gate array (FPGA), and/or a processor with controlling software, or combinations thereof.

Additionally, the terms “couple,” “coupled,” or “couples,” where may be used herein, are intended to mean either a direct or an indirect connection. Thus, if a first device couples, or is coupled to, a second device, that connection may be by way of a direct connection or through an indirect connection via other devices (or components) and connections.

Regarding, the use herein of terms such as “an embodiment,” “one embodiment,” an “exemplary embodiment,” a “particular embodiment,” or other similar terminology, these terms are intended to indicate that a specific feature, structure, function, operation, or characteristic described in connection with the embodiment is found in at least one embodiment of the present disclosure. Therefore, the appearances of phrases such as “in one embodiment,” “in an embodiment,” “in an exemplary embodiment,” etc., may, but do not necessarily, all refer to the same embodiment, but rather, mean “one or more but not all embodiments” unless expressly specified otherwise. Further, the terms “comprising,” “having,” “including,” and variations thereof, are used in an open-ended manner and, therefore, should be interpreted to mean “including, but not limited to . . . ” unless expressly specified otherwise. Also, an element that is preceded by “comprises . . . a” does not, without more constraints, preclude the existence of additional identical elements in the subject process, method, system, article, or apparatus that includes the element.

The terms “a,” “an,” and “the” also refer to “one or more” unless expressly specified otherwise. In addition, the phrase “at least one of A and B” as may be used herein and/or in the following claims, whereby A and B are variables indicating a particular object or attribute, indicates a choice of A or B, or both A and B, similar to the phrase “and/or.” Where more than two variables are present in such a phrase, this phrase is hereby defined as including only one of the variables, any one of the variables, any combination (or sub-combination) of any of the variables, and all of the variables.

Further, where used herein, the term “about” or “approximately” applies to all numeric values, whether or not explicitly indicated. These terms generally refer to a range of numeric values that one of skill in the art would consider equivalent to the recited values (e.g., having the same function or result). In certain instances, these terms may include numeric values that are rounded to the nearest significant figure.

In addition, any enumerated listing of items that is set forth herein does not imply that any or all of the items listed are mutually exclusive and/or mutually inclusive of one another, unless expressly specified otherwise. Further, the term “set,” as used herein, shall be interpreted to mean “one or more,” and in the case of “sets,” shall be interpreted to mean multiples of (or a plurality of) “one or more,” “ones or more,” and/or “ones or mores” according to set theory, unless expressly specified otherwise.

The foregoing detailed description has been presented for purposes of illustration and description. It is not intended to be exhaustive or be limited to the precise form disclosed. Many modifications and variations are possible in light of the above description. The described embodiments were chosen to best explain the principles of the technology and its practical application to thereby enable others skilled in the art to best utilize the technology in various embodiments and with various modifications as are suited to the particular use contemplated. The scope of the technology is defined by the claims appended hereto.

What is claimed is:

1. A method of programming a memory device, comprising the steps of:
preparing a memory device that includes a plurality of memory blocks that each include a plurality of memory cells that are arranged in a plurality of word lines, the plurality of memory blocks including a plurality of hybrid memory blocks that are able to operate in a single bit per memory cell (SLC) mode and a multiple bits per memory cell mode;
programming a selected word line of the plurality of word lines within a selected hybrid memory block to an SLC format, the programming of the selected word line to the SLC format comprising the steps of:
determining which zone within the selected hybrid memory block the selected word line is located in,
setting an SLC programming voltage to a level based on the determination of the zone of the selected word line, and
applying a programming pulse at the SLC programming voltage to the selected word line to program the memory cells of the selected word line.

2. The method of programming the memory device as sets forth in claim 1, wherein the plurality of memory blocks further includes a plurality of dedicated SLC memory blocks that are only configured to operate in the SLC mode.

3. The method of programming the memory device as set forth in claim 1, wherein the memory cells of the word lines of the dedicated SLC memory blocks are programmed with a programming pulse at a VPGMSLC voltage.

4. The method of programming the memory device as set forth in claim 3, wherein the step of setting the SLC programming voltage includes determining a AVPGMSLC voltage based on which zone the selected word line is located in and setting the SLC programming voltage to a level that is equal to VPGMSLC minus AVPGMSLC.

5. The method of programming the memory device as set forth in claim 3 further including, during a background operation, the step of programming any data written to SLC format in either the dedicated SLC memory blocks or the hybrid memory blocks to a multiple bits per memory cell format.

6. The method of programming the memory device as set forth in claim 5, wherein the multiple bits per memory cell format includes at least three bits per memory cell.

7. The method of programming the memory device as set forth in claim 1 further including the step of determining if the programming of the selected word line is to include multiple programming pulses and at least one verify operation or is to include only a single programming pulse and no verify operations based on the determination of which zone the selected word line is located within.

8. A memory device, comprising:
a plurality of memory blocks that each include a plurality of memory cells that are arranged in a plurality of word lines, the plurality of memory blocks including a plurality of hybrid memory blocks that are able to operate in a single bit per memory cell (SLC) mode and a multiple bits per memory cell mode;
control circuitry configured to program a selected word line of the plurality of word lines within a selected hybrid memory block to an SLC format, the control circuitry being configured to:
determine which zone within the selected hybrid memory block the selected word line is located in,
set an SLC programming voltage to a level based on the determination of the zone of the selected word line, and
apply a programming pulse at the SLC programming voltage to the selected word line to program the memory cells of the selected word line.

9. The memory device as set forth in claim 8, wherein the plurality of memory blocks further includes a plurality of dedicated SLC memory blocks that are only configured to operate in the SLC mode.

10. The memory device as set forth in claim 8, wherein the control circuitry of the memory device is configured to program the memory cells of the word lines of the dedicated SLC memory blocks with a programming pulse at a VPGMSLC voltage.

11. The memory device as set forth in claim 10, wherein while setting the SLC programming voltage, the control circuitry is configured to determine a AVPGMSLC voltage based on which zone the selected word line is located in and set the SLC programming voltage to a level that is equal to VPGMSLC minus AVPGMSLC.

12. The memory device as set forth in claim 10, wherein the control circuitry is configured to, during a background operation, program any data written to SLC format in either the dedicated SLC memory blocks or the hybrid memory blocks to a multiple bits per memory cell format.

13. The memory device as set forth in claim 12, wherein the multiple bits per memory cell format includes at least three bits per memory cell.

14. The memory device as set forth in claim 8, wherein the control circuitry is further configured to determine if the programming of the selected word line is to include multiple programming pulses and at least one verify operation or is to include only a single programming pulse and no verify operations based on the determination of which zone the selected word line is located within.

15. An apparatus, comprising:
a plurality of memory blocks that each include a plurality of memory cells that are arranged in a plurality of word lines, the plurality of memory blocks including a plurality of hybrid memory blocks that are able to operate in a single bit per memory cell (SLC) mode and a multiple bits per memory cell mode and the plurality of memory blocks including a plurality of dedicated SLC memory blocks that are only able to operate in the SLC mode;
a programming means for programming the memory cells of a selected word line within a selected hybrid memory block to an SLC format, the programming means being configured to:
determine which zone within the selected hybrid memory block the selected word line is located in,
set an SLC programming voltage to a level based on the determination of the zone of the selected word line, and
apply a programming pulse at the SLC programming voltage to the selected word line to program the memory cells of the selected word line.

16. The apparatus as set forth in claim 15, wherein the plurality of memory blocks further includes a plurality of dedicated SLC memory blocks that are only configured to operate in the SLC mode.

17. The apparatus as set forth in claim 15, wherein the programming means is configured to program the memory cells of the word lines of the dedicated SLC memory blocks with a programming pulse at a VPGMSLC voltage.

18. The apparatus as set forth in claim 17, wherein while setting the SLC programming voltage, the programming means is configured to determine a AVPGMSLC voltage based on which zone the selected word line is located in and set the SLC programming voltage to a level that is equal to VPGMSLC minus AVPGMSLC.

19. The apparatus as set forth in claim 16, wherein the programming means is configured to, during a background operation, program any data written to SLC format in either the dedicated SLC memory blocks or the hybrid memory blocks to a multiple bits per memory cell format.

20. The apparatus as set forth in claim 15 wherein the programming means is configured to determine if the programming of the selected word line is to include multiple programming pulses and at least one verify operation or is to include only a single programming pulse and no verify operations based on the determination of which zone the selected word line is located within.
